(19) United States
(12) Patent Application Publication
(10) Pub. No.: US 2025/0107185 A1
(43) Pub. Date: Mar. 27, 2025

(54) SEMICONDUCTOR DEVICES AND METHODS OF MANUFACTURING THE SAME

(71) Applicant: SAMSUNG ELECTRONICS CO., LTD., Suwon-si (KR)

(72) Inventors: Hyohoon BYEON, Suwon-si (KR); Seokhoon Kim, Suwon-si (KR); Pankwi Park, Suwon-si (KR); Sungkeun Lim, Suwon-si (KR); Yuyeong Jo, Suwon-si (KR)

(21) Appl. No.: 18/738,197

(22) Filed: Jun. 10, 2024

(30) Foreign Application Priority Data
Sep. 21, 2023 (KR) 10-2023-0126405

(51) Int. Cl. H01L 29/08; H01L 21/02; H01L 29/06; H01L 29/423; H01L 29/66; H01L 29/775; H01L 29/786

(52) U.S. Cl. CPC H10D 62/151; H01L 21/02532; H10D 30/014; H10D 30/031; H10D 30/43; H10D 30/6735; H10D 30/6757; H10D 62/121; H10D 64/017

(57) ABSTRACT

A semiconductor device includes a substrate including an active pattern, a channel pattern on the active pattern, and including a plurality of semiconductor patterns spaced apart from each other and vertically stacked, a gate electrode on the plurality of semiconductor patterns, and extending in a first horizontal direction, a gate spacer disposed on a sidewall of the gate electrode in a second horizontal direction crossing the first horizontal direction, a source/drain pattern electrically connected to the plurality of semiconductor patterns, and including a first epitaxial pattern and a second epitaxial pattern on a side surface of the first epitaxial pattern in the second horizontal direction, and a protection pattern between at least one of the plurality of semiconductor patterns and the gate spacer and including a material having an etch selectivity with the first epitaxial pattern.

### REFERENCE TO RELATED APPLICATIONS

This application is based on and claims priority under 35 U.S.C. § 119 to Korean Patent Application No. 10-2023-0126405, filed on Sep. 21, 2023, in the Korean Intellectual Property Office, the disclosure of which is incorporated by reference herein in its entirety.

### BACKGROUND OF THE INVENTION

The inventive concept of the present application relates to semiconductor devices and methods of manufacturing the same, and more particularly, to semiconductor devices including a field-effect transistor and methods of manufacturing the semiconductor devices.

Semiconductor devices may include an integrated circuit including metal-oxide-semiconductor field-effect transistors (MOSFETs). As sizes and design rules of semiconductor devices are gradually reduced, the scaling down of MOSFETs may be progressed. Due to the scaling down of MOSFETs, operating characteristics of semiconductor devices may change (e.g., deteriorate). Accordingly, various methods of forming semiconductor devices having excellent (e.g., improved or maintained) performance while overcoming the limitations due to high integration of semiconductor devices have been researched.

### SUMMARY OF THE INVENTION

The inventive concept of the present application may provide semiconductor devices with improved electrical characteristics.

The inventive concept of the present application may provide methods of manufacturing semiconductor devices with improved electrical characteristics.

According to an aspect of the inventive concept, there is provided a semiconductor device including a substrate that includes an active pattern; a channel pattern on the active pattern, wherein the channel pattern includes a plurality of semiconductor patterns that are stacked and spaced apart from each other in a first direction; a gate electrode on the plurality of semiconductor patterns, wherein the gate electrode extends in a second direction; a gate spacer on a sidewall of the gate electrode in a third direction; a source/drain pattern that is electrically connected to the plurality of semiconductor patterns, wherein the source/drain pattern includes a first epitaxial pattern and a second epitaxial pattern that is on a side surface of the first epitaxial pattern in the third direction; and a protection pattern between at least one of the plurality of semiconductor patterns and the gate spacer, wherein the protection pattern includes a material that has an etch selectivity with the first epitaxial pattern, wherein the first direction is perpendicular to an upper surface of the substrate, wherein the second direction is parallel with the upper surface of the substrate, and wherein the third direction is parallel with the upper surface of the substrate and intersects the second direction.

According to another aspect of the inventive concept, there is provided a semiconductor device including a substrate that includes an active pattern; a channel pattern on the active pattern, wherein the channel pattern includes a plurality of semiconductor patterns that are stacked and spaced apart from each other in a first direction; a gate electrode on the plurality of semiconductor patterns, wherein the gate electrode extends in a second direction; a gate spacer on a sidewall of the gate electrode in a third direction; a source/drain pattern that is electrically connected to the plurality of semiconductor patterns, wherein the source/drain pattern includes a first epitaxial pattern and a second epitaxial pattern that is on a side surface of the first epitaxial pattern in the third direction; and a protection pattern between at least one of the plurality of semiconductor patterns and the gate spacer, wherein the protection pattern includes a material that has an etch selectivity with the first epitaxial pattern, wherein the protection pattern is on an upper surface of an uppermost semiconductor pattern among the plurality of semiconductor patterns, wherein the first direction is perpendicular to an upper surface of the substrate, wherein the second direction is parallel with the upper surface of the substrate, and wherein the third direction is parallel with the upper surface of the substrate and intersects the second direction.

According to another aspect of the inventive concept, there is provided a semiconductor device including a substrate that includes an active region; an active pattern in the active region; a device isolation layer that is adjacent the active pattern; a channel pattern on the active pattern, wherein the channel pattern includes a plurality of semiconductor patterns that are stacked and spaced apart from each other in a first direction; a gate electrode on the channel pattern, wherein the gate electrode extends in a second direction; a gate insulating layer between the gate electrode and the channel pattern; a gate spacer on a sidewall of the gate electrode in a third direction; a source/drain pattern that is electrically connected to the plurality of semiconductor patterns, wherein the source/drain pattern includes a first epitaxial pattern and a second epitaxial pattern that is on a side surface of the first epitaxial pattern in the third direction; a protection pattern between at least one of the plurality of semiconductor patterns and the gate spacer, wherein the protection pattern includes a material that has an etch selectivity with the first epitaxial pattern; a gate capping pattern on an upper surface of the gate electrode; an interlayer insulating layer on the gate capping pattern; an active contact that extends in the interlayer insulating layer and is electrically connected to the source/drain pattern; a gate contact that extends in the interlayer insulating layer and the gate capping pattern and is electrically connected to the gate electrode; and a first metal layer in the interlayer insulating layer, wherein the first metal layer includes a power wiring, and first wirings that are electrically connected to the active contact and the gate contact, respectively, wherein the first direction is perpendicular to an upper surface of the substrate, wherein the second direction is parallel with the upper surface of the substrate, and wherein the third direction is parallel with the upper surface of the substrate and intersects the second direction.

The protection pattern may be disposed between the semiconductor pattern and the gate spacer. The protection pattern may contact source/drain edge portions of the semiconductor pattern and the second epitaxial pattern. The protection pattern may include the material having etch selectivity with the sacrificial layer. For this reason, when an etching process is performed on the sacrificial layer, the source/drain edge portion having a relatively thin thickness in the second direction may not be damaged. This may prevent a defect in which the gate electrode and the first epitaxial pattern are short when forming the gate electrode. For the above reasons, the electrical characteristics and reliability of the semiconductor device may be improved.

### BRIEF DESCRIPTION OF THE DRAWINGS

Embodiments of the inventive concept of the present application will be more clearly understood from the following detailed description taken in conjunction with the accompanying drawings in which:

FIGS. 1 to 3 are simplified diagrams for explaining logic cells of a semiconductor device according to some embodiments;

FIG. 4 is a plan view for explaining a semiconductor device according to some embodiments;

FIGS. 5A to 5D are cross-sectional views taken along lines A-A′, B-B′, C-C′, and D-D′ of FIG. 4, respectively;

FIG. 6A is an enlarged view showing region M of FIG. 5A, according to some embodiments;

FIG. 6B is an enlarged view showing region N of FIG. 5D, according to some embodiments;

FIG. 7A is a cross-sectional view taken along line I-I′ of FIG. 6A, according to some embodiments;

FIG. 7B is a plan view taken along line II-II′ of FIG. 6A, according to some embodiments;

FIG. 7C is a plan view taken along line III-III′ of FIG. 6A, according to some embodiments;

FIG. 8 is a plan view taken along line II-II′ of FIG. 6A, according to some embodiments;

FIG. 9A is a plan view taken along line II-II′ of FIG. 6A, according to some embodiments;

FIG. 9B is a plan view taken along line III-III′ of FIG. 6A, according to some embodiments; and

FIGS. 10A to 15B are cross-sectional views for explaining a method of manufacturing a semiconductor device according to some embodiments.

### DETAILED DESCRIPTION

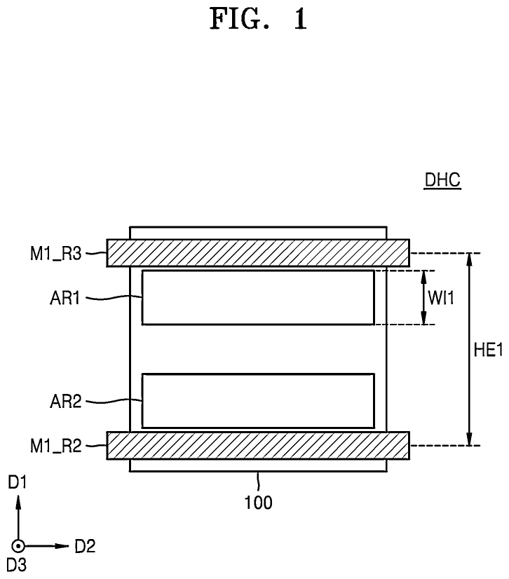

FIGS. 1 to 3 are simplified diagrams for explaining logic cells of a semiconductor device according to some embodiments.

Referring to FIG. 1, a single height cell SHC may be provided. Specifically, a first power wiring M1_R1 and a second power wiring M1_R2 may be provided on a substrate 100. The first power wiring M1_R1 may be a path through which a source voltage VSS, for example, a ground voltage, is provided. The second power wiring M1_R2 may be a path through which a drain voltage VDD, for example, a power voltage, is provided.

The single height cell SHC may be defined between (a (central) portion in a first direction D1 of) the first power wiring M1_R1 and (a (central) portion in the first direction D1 of) the second power wiring M1_R2. The single height cell SHC may include one first active region AR1 and one second active region AR2. One of the first and second active regions AR1 and AR2 may be a PMOSFET region, and the other of the first and second active regions AR1 and AR2 may be an NMOSFET region. In other words, the single height cell SHC may have a CMOS structure provided between (a (central) portion in a first direction D1 of) the first power wiring M1_R1 and (a (central) portion in a first direction D1 of) the second power wiring M1_R2.

Each of the first and second active regions AR1 and AR2 may have a first length WI in the first direction D1. A length of the single height cell SHC in the first direction D1 may be defined as a first height HE1. The first height HE1 may be (substantially) the same as a distance (e.g., pitch) between (a (central) portion in the first direction D1 of) the first power wiring M1_R1 and (a (central) portion in the first direction D1 of) the second power wiring M1_R2.

The single height cell SHC may constitute one logic cell. In this specification, a logic cell may refer to a logic device (e.g., AND, OR, XOR, XNOR, inverter, etc.) that performs a specific function. That is, the logic cell may include transistors configuring the logic device and wirings connecting (e.g., electrically connecting) the transistors to each other. It will be understood that when an element or layer is referred to as being “connected to”, or “coupled to”, another element or layer, it may be directly on, connected to, or coupled to the other element or layer, or one or more intervening elements or layers may be present. In contrast, when an element is referred to as being “directly coupled,” “directly connected,” or “directly responsive” to, or “directly on,” another element, there are no intervening elements present. In addition, “electrical connection” conceptually includes a physical connection and a physical disconnection.

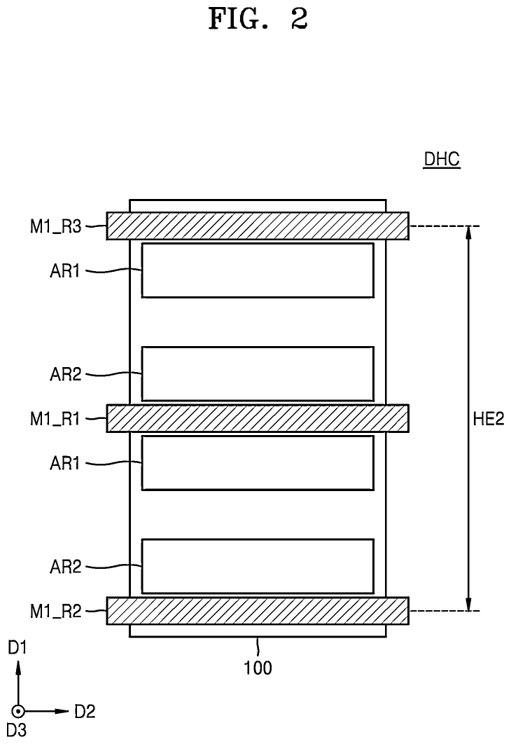

Referring to FIG. 2, a double height cell DHC may be provided. Specifically, the first power wiring M1_R1, the second power wiring M1_R2, and a third power wiring M1_R3 may be provided on the substrate 100. The first power wiring M1_R1 may be disposed between the second power wiring M1_R2 and the third power wiring M1_R3 (in the first direction D1). The third power wiring M1_R3 may be a path through which the source voltage VSS is provided.

The double height cell DHC may be defined between (a (central) portion in the first direction D1 of) the second power wiring M1_R2 and (a (central) portion in the first direction D1 of) the third power wiring M1_R3. The double height cell DHC may include two first active regions AR1 and two second active regions AR2.

One of the two second active regions AR2 may be adjacent to the second power wiring M1_R2. The other of the two second active regions AR2 may be adjacent to the third power wiring M1_R3. The two first active regions AR1 may be adjacent to the first power wiring M1_R1. In a plan view, the first power wiring M1_R1 may be disposed between the two first active regions AR1 (in the first direction D1).

A length of the double height cell DHC in the first direction D1 may be defined as a second height HE2. The second height HE2 may be approximately twice the first height HE1 of FIG. 1. The two first active regions ARI of the double height cell DHC may be tied together to operate as one active region.

In the inventive concept of the present application, the double height cell DHC shown in FIG. 2 may be defined as a multi height cell. Although not shown, a multi height cell may include a triple height cell having a cell height approximately three times that of the single height cell SHC.

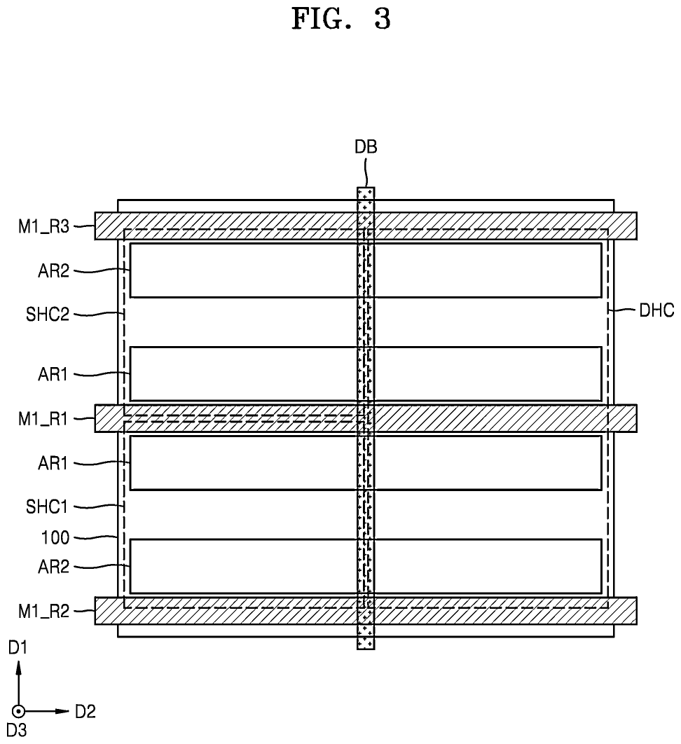

Referring to FIG. 3, a first single height cell SHC1, a second single height cell SHC2, and the double height cell DHC may be two-dimensionally disposed on the substrate 100. The first single height cell SHC1 may be disposed between the first and second power wirings M1_R1 and M1_R2. The second single height cell SHC2 may be disposed between the first and third power wirings M1_R1 and M1_R3. The second single height cell SHC2 may be adjacent to the first single height cell SHC1 in the first direction D1.

The double height cell DHC may be disposed between the second and third power wirings M1_R2 and M1_R3. The double height cell DHC may be adjacent to the first and second single height cells SHC1 and SHC2 in a second direction D2.

A separation structure DB may be provided between the first single height cell SHC1 and the double height cell DHC, and between the second single height cell SHC2 and the double height cell DHC. By the separation structure DB, an active region (e.g., the first active region AR1 and/or the second active region AR2) of the double height cell DHC may be electrically separated from an active region (e.g., the first active region AR1 and/or the second active region AR2) of each of the first and second single height cells SHC1 and SHC2. As used herein, the term “and/or” includes any and all combinations of one or more of the associated listed items. Expressions such as “at least one of,” when preceding a list of elements, modify the entire list of elements and do not modify the individual elements of the list.

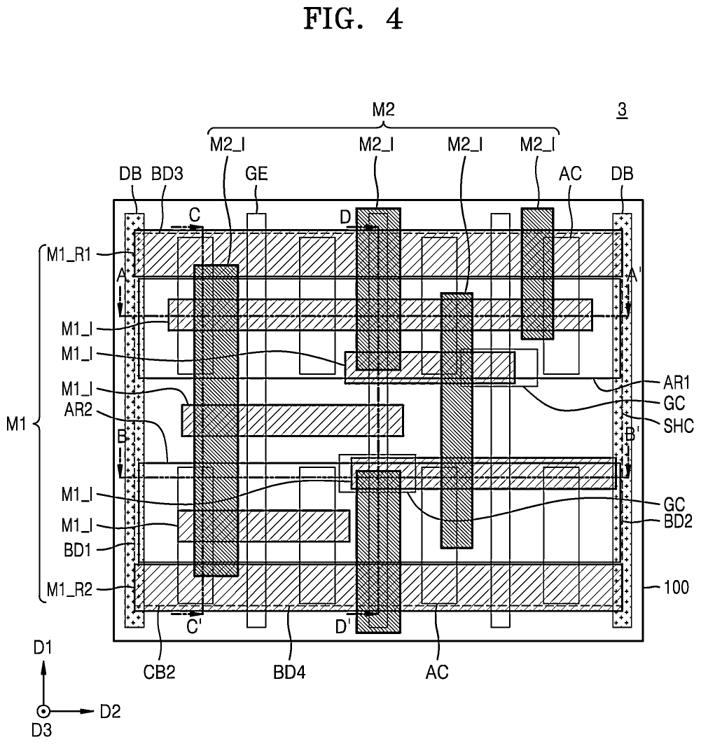

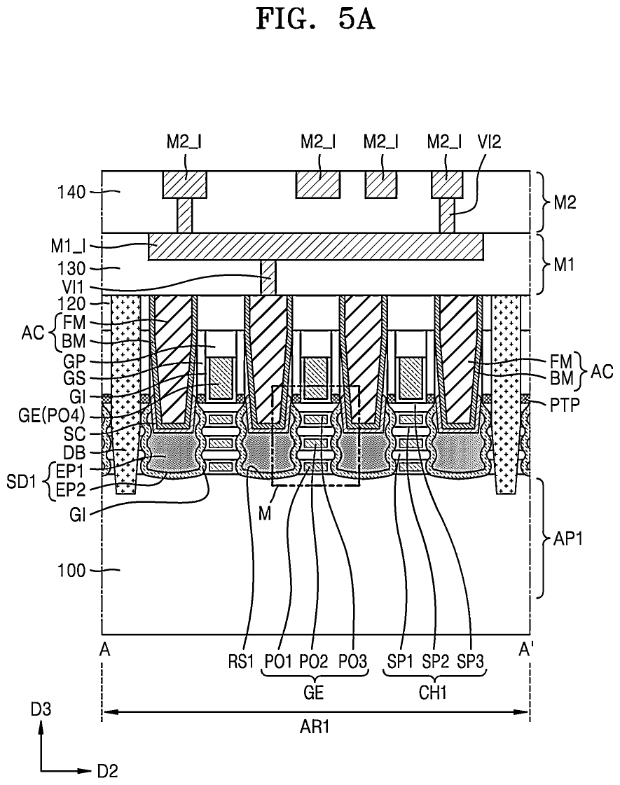

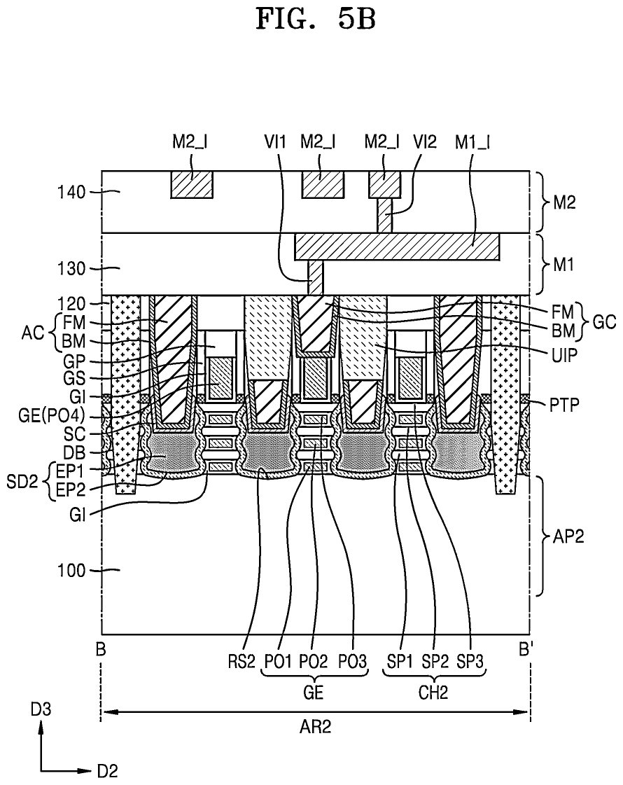

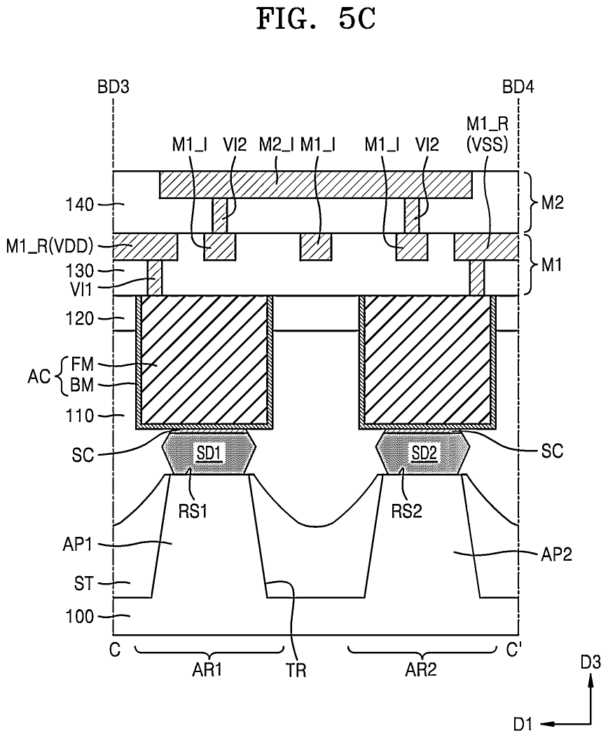

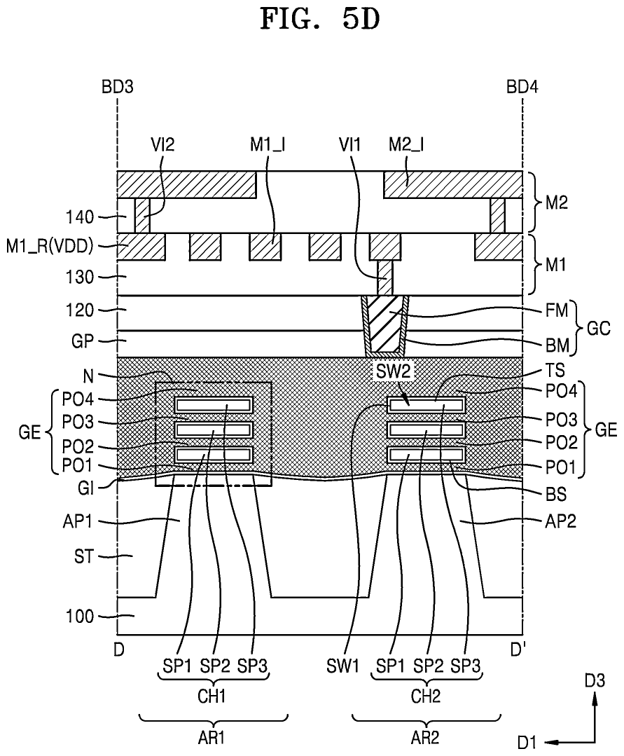

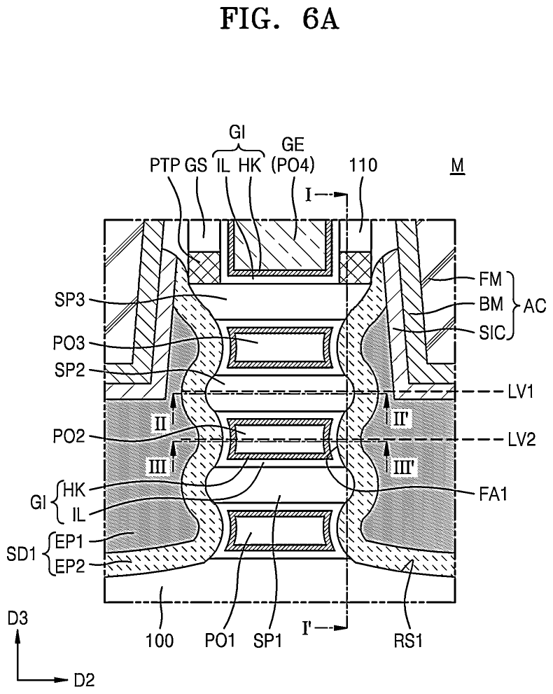

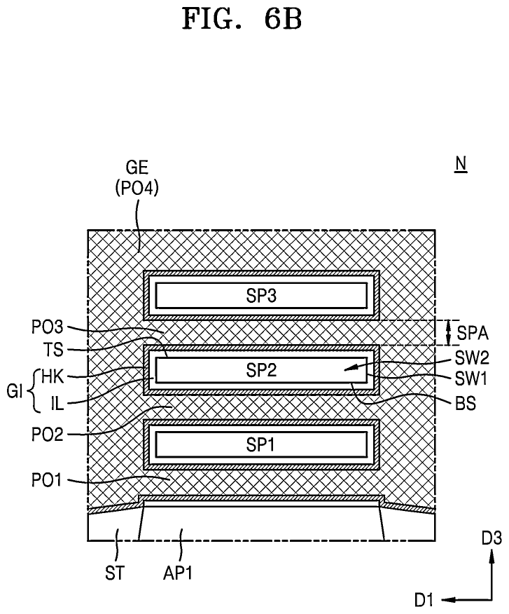

FIG. 4 is a plan view for explaining a semiconductor device 3 according to some embodiments. FIGS. 5A to 5D are cross-sectional views taken along lines A-A′, B-B′, C-C′, and D-D′ of FIG. 4, respectively. FIG. 6A is an enlarged view showing region M of FIG. 5A according to some embodiments. FIG. 6B is an enlarged view showing region N of FIG. 5D according to some embodiments. The semiconductor device 3 shown in FIGS. 4 and 5A to 5D may be an example more specifically showing the single height cell SHC of FIG. 1.

Referring to FIGS. 4, 5A to 5D, 6a, and 6b, the single height cell SHC may be provided on the substrate 100. Logic transistors constituting a logic circuit may be disposed on the single height cell SHC. The substrate 100 may be a semiconductor substrate including silicon (Si), germanium (Ge), silicon-germanium (SiGe), etc., or a compound semiconductor substrate. As an example, the substrate 100 may be a silicon substrate. As an example, the substrate 100 may be a single crystal silicon, germanium, or silicon-germanium substrate. When the substrate 100 includes a single crystal silicon, germanium, or silicon-germanium substrate, the substrate 100 may have a surface 100, 110, or 111 (in Miller index) as a main surface.

The substrate 100 may include the first active region ARI and the second active region AR2. Each of the first and second active regions AR1 and AR2 may extend in the second direction D2. In some embodiments, the first active region AR1 may be an NMOSFET region, and the second active region AR2 may be a PMOSFET region.

The first active pattern AP1 and the second active pattern AP2 may be defined by a trench TR formed in an upper portion of the substrate 100. The first active pattern AP1 may be provided on the first active region AR1, and the second active pattern AP2 may be provided on the second active region AR2. The first and second active patterns AP1 and AP2 may extend in the second direction D2. The first and second active patterns AP1 and AP2 may be parts of the substrate 100 and may be vertically protruding parts (in a third direction D3).

A device isolation layer ST may be provided on (or in) the substrate 100. The device isolation layer ST may (at least partially) fill the trench TR. The device isolation layer ST may include, for example, a silicon oxide layer. The device isolation layer ST may not be disposed on (e.g., not cover or not overlap) the first and second channel patterns CH1 and CH2, which will be described below. As used herein, “an element A overlapping an element B in a direction X” (or similar language) means that there is at least one line that extends in the direction X and intersects both the elements A and B.

The first channel pattern CH1 may be provided on the first active pattern AP1. The second channel pattern CH2 may be provided on the second active pattern AP2. Each of the first channel pattern CH1 and second channel pattern CH2 may include the first semiconductor pattern SP1, the second semiconductor pattern SP2, and the third semiconductor pattern SP3 which are sequentially stacked. The first, second, and third semiconductor patterns SP1, SP2, and SP3 may be spaced apart from each other in a vertical direction (e.g., the third direction D3).

Each of the first, second, and third semiconductor patterns SP1, SP2, and SP3 may include, for example, silicon, germanium, or silicon-germanium. For example, each of the first, second, and third semiconductor patterns SP1, SP2, and SP3 may include crystalline silicon.

A plurality of first source/drain patterns SD1 may be provided on the first active pattern AP1. A plurality of first recesses RS1 may be formed in the first active pattern AP1. The first source/drain patterns SD1 may be respectively provided in the first recesses RS1. The first source/drain patterns SD1 may be impurity regions of a first conductivity type (e.g., n-type). The first channel pattern CH1 may be disposed between a pair of the (adjacent) first source/drain patterns SD1. In other words, the stacked first, second, and third semiconductor patterns SP1, SP2, and SP3 may connect (e.g., electrically connect) the pair of the (adjacent) first source/drain patterns SD1 to each other.

A plurality of second source/drain patterns SD2 may be provided on the second active pattern AP2. A plurality of second recesses RS2 may be formed in the second active pattern AP2. The second source/drain patterns SD2 may be respectively provided in the second recesses RS2. The second source/drain patterns SD2 may be impurity regions of a second conductivity type (e.g., p-type). The second channel pattern CH2 may be disposed between a pair of the (adjacent) second source/drain patterns SD2. In other words, the stacked first, second, and third semiconductor patterns SP1, SP2, and SP3 may connect (e.g., electrically connect) the pair of the (adjacent) second source/drain patterns SD2 to each other.

The first and second source/drain patterns SD1 and SD2 may respectively include a first epitaxial pattern EP1 and a second epitaxial pattern EP2. The second epitaxial pattern EP2 may be on (e.g., cover or overlap) sidewalls and lower (e.g., lowermost) surface of the first recess RS1 and/or the second recess RS2. The second epitaxial pattern EP2 may be on (e.g., cover or overlap) a lower (e.g., the lowermost) surface and a side surface of the first epitaxial pattern EP1. For example, the second epitaxial pattern EP2 may extend around (e.g., at least partially surround) the first epitaxial pattern EP1 in the first recess RS1 and/or the second recess RS2.

The first epitaxial pattern EP1 and the second epitaxial pattern EP2 may be formed through a selective epitaxial growth (SEG) process. For example, an upper (e.g., the uppermost) surface of each of the first and second source/drain patterns SD1 and SD2 may be higher than an upper (e.g., the uppermost) surface of the third semiconductor pattern SP3. As another example, the upper (e.g., the uppermost) surface of at least one of the first and second source/drain patterns SD1 and SD2 may be located at (substantially) the same level as the upper (e.g., the uppermost) surface of the third semiconductor pattern SP3. The vertical level may be a relative location (e.g., a distance) from a lower surface of the substrate 100 in a vertical direction (e.g., the third direction D3). For example, when element A is higher than element B, element A may be located farther than element B from the lower surface of the substrate 100 in the vertical direction (e.g., the third direction D3).

In some embodiments, the first source/drain patterns SD1 may each include the same semiconductor element (e.g., Si) as that of the substrate 100, and the second source/drain patterns SD2 may each include a semiconductor element (e.g., SiGe) having a lattice constant greater than a lattice constant of a semiconductor element of the substrate 100. Accordingly, the pair of the (adjacent) second source/drain patterns SD2 may provide compressive stress to the second channel pattern CH2 therebetween.

A sidewall of each of the first and second source/drain patterns SD1 and SD2 may have an uneven embossed shape. In other words, the sidewall of each of the first and second source/drain patterns SD1 and SD2 may have a wavy profile. The sidewall of each of the first and second source/drain patterns SD1 and SD2 may protrude toward first to third gate portions PO1, PO2, and PO3 of a gate electrode GE, which will be described below.

The gate electrodes GE may be provided crossing (e.g., overlapping) the first and second channel patterns CH1 and CH2 and extending in the first direction D1. The gate electrodes GE may be disposed (e.g., arranged) in the second direction D2 according to a first pitch. The gate electrodes GE may vertically overlap the first and second channel patterns CH1 and CH2 respectively.

In the specification, the first direction D1 is defined as a direction parallel to the upper (e.g., the uppermost) surface of the substrate 100, the second direction D2 is defined as a direction parallel to the upper (e.g., the uppermost) surface of the substrate 100 and crossing (e.g., intersecting) the first direction D1, and the third direction D3 is defined as a direction perpendicular to the upper (e.g., the uppermost) surface of the substrate 100. The first direction D1 may be referred to as a first horizontal direction, the second direction D2 may be referred to as a second horizontal direction, and the third direction D3 may be referred to as a vertical direction.

The gate electrode GE may include a first gate portion PO1 disposed between the first or second active pattern AP1 or AP2 and the first semiconductor pattern SP1, a second gate portion PO2 disposed between the first semiconductor pattern SP1 and the second semiconductor pattern SP2, a third gate portion PO3 disposed between the second semiconductor pattern SP2 and the third semiconductor pattern SP3, and a fourth gate portion PO4 on the third semiconductor pattern SP3.

Referring to FIG. 5D, the gate electrode GE may be provided on an upper (e.g., the uppermost) surface TS, a lower (e.g., the lowermost) surface BS, and first sidewalls SW1 of each of the first to third semiconductor patterns SP1 to SP3. In other words, a transistor according to the embodiment may be a three-dimensional FET (e.g., MBCFET or GAAFET) in which the gate electrode GE three-dimensionally extends around (at least partially surrounds) a channel. The first sidewalls SW1 may be defined as sidewalls of each of the first, second, and third semiconductor patterns SP1, SP2, and SP3 in the first direction D1. The gate electrode GE may not be disposed on second sidewalls SW2 of each of the first, second, and third semiconductor patterns SP1, SP2, and SP3. The second sidewalls SW2 may be defined as sidewalls of each of the first, second, and third semiconductor patterns SP1, SP2, and SP3 in the second direction D2.

Referring again to FIGS. 4, 5A to 5D, 6A, and 6B, a pair of gate spacers GS may be disposed on both sidewalls of the fourth gate portion PO4 of the gate electrode GE. For example, the pair of gate spacers GS may be separated by the fourth gate portion PO4 of the gate electrode GE. The gate spacers GS may extend in the first direction D1 along the gate electrode GE (e.g., the fourth gate portion PO4). Upper (e.g., uppermost) surfaces of the gate spacers GS may be higher than an upper (e.g., the uppermost) surface of the gate electrode GE. The upper (e.g., the uppermost) surfaces of the gate spacers GS may be coplanar with an upper (e.g., the uppermost) surface of a first interlayer insulating layer 110, which will be described below. In some embodiments, the gate spacers GS may include, for example, SiCN, SiCON, and/or SiN. In some embodiments, the gate spacers GS may include a multi-layer including, for example, at least two of SiCN, SiCON, and SiN.

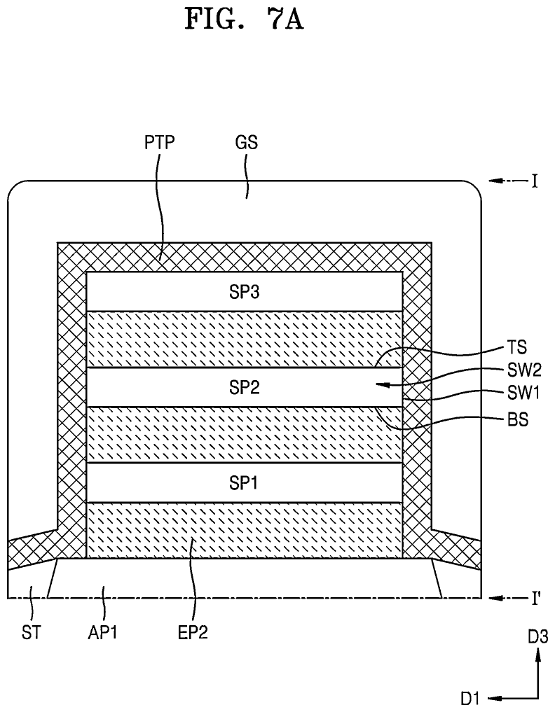

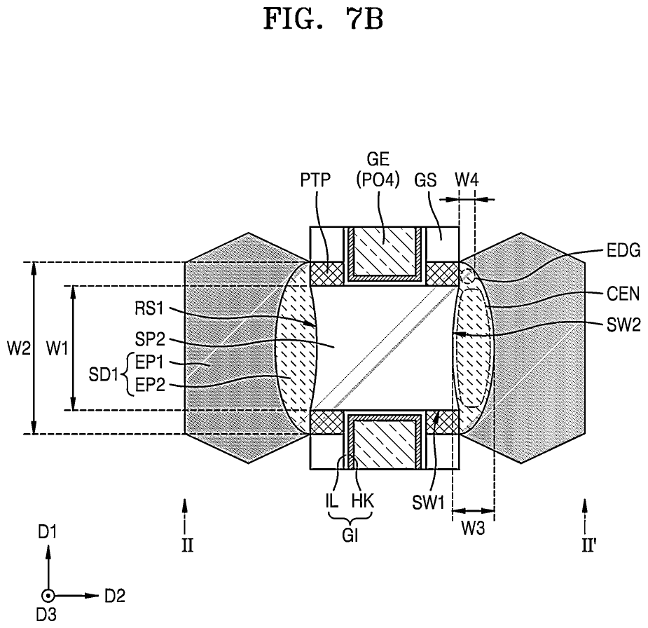

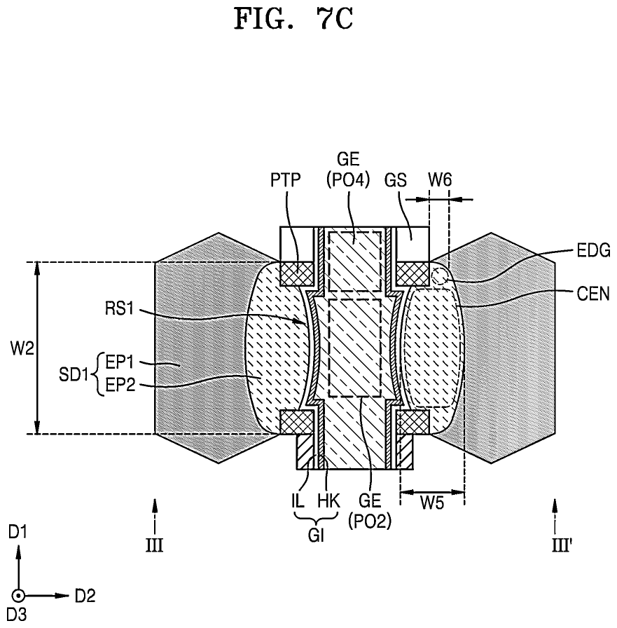

A protection pattern PTP may be disposed on the sidewall of the fourth portion PO4 of the gate electrode GE. The protection pattern PTP may be disposed between the gate spacer GS and the third semiconductor pattern SP3. The gate spacer GS and the third semiconductor pattern SP3 may be spaced apart from each other with the protection pattern PTP therebetween. The protection pattern PTP will be described in detail below with reference to FIGS. 7A to 7C.

A gate capping pattern GP may be provided on the gate electrode GE. The gate capping pattern GP may extend in the first direction D1 along the gate electrode GE. The gate capping pattern GP may include a material having etch selectivity with first and second interlayer insulating layers 110 and 120, which will be described below. Specifically, the gate capping pattern GP may include, for example, SiON, SiCN, SiCON, and/or SiN.

A gate insulating layer GI may be disposed between the gate electrode GE and the first channel pattern CH1 and between the gate electrode GE and the second channel pattern CH2. The gate insulating layer GI may be on (e.g., cover or overlap) the upper (e.g., the uppermost) surface TS, the lower (e.g., the lowermost) surface BS, and the first sidewalls SW1 of each of the first, second, and third semiconductor patterns SP1, SP1, and SP3. The gate insulating layer GI may be on (e.g., cover or overlap) the upper surface of the device isolation layer ST below the gate electrode GE. The gate insulating layer GI may be disposed between the gate electrode GE and (the upper surface or the uppermost surface of) the first active pattern AP1 and the gate electrode GE and (the upper surface or the uppermost surface of) the second active pattern AP2. The gate insulating layer GI may not be disposed between the third semiconductor pattern SP3 and the protection pattern PTP.

Each of the first, second, and third portions PO1, PO2, and PO3 of the gate electrode GE may have a concave sidewall. The concave sidewall of each of the first, second, and third portions PO1, PO2, and PO3 may correspond to the protruding sidewall of the first source/drain pattern SD1 or the protruding sidewall of the second source/drain pattern SD2.

Representatively, the second portion PO2 of the gate electrode GE and the gate insulating layer GI adjacent to the second portion PO2 are described. The gate insulating layer GI may be disposed between the second portion PO2 and the first semiconductor pattern SP1, between the second portion PO2 and the second semiconductor pattern SP2, and between the second portion PO2 and the first source/drain pattern SD1 (e.g., the second epitaxial pattern EP2 of the first source/drain pattern SD1).

The gate insulating layer GI may include an interface layer IL and a high-k dielectric layer HK. The interface layer IL may be directly on (e.g., may be directly in contact with) the first semiconductor pattern SP1, the second semiconductor pattern SP2, and the first source/drain pattern SD1. The high-k dielectric layer HK may be disposed between the interface layer IL and the second portion PO2. The high-k dielectric layer HK may be directly on (e.g., may be directly in contact with) a surface of the second portion PO2.

The interface layer IL may include, for example, a silicon oxide layer or a silicon oxynitride layer. The high-k dielectric layer HK may include a high-k dielectric constant material having a higher dielectric constant than the silicon oxide layer. As an example, the high-k dielectric layer HK may include hafnium oxide, hafnium silicon oxide, hafnium zirconium oxide, hafnium tantalum oxide, lanthanum oxide, zirconium oxide, zirconium silicon oxide, tantalum oxide, titanium oxide, barium strontium titanium oxide, barium titanium oxide, strontium titanium oxide, lithium oxide, aluminum oxide, lead scandium tantalum oxide, and/or lead zinc niobate.

As an example, the gate insulating layer GI may include a ferroelectric material layer. As another example, the gate insulating layer GI may include a plurality of ferroelectric material layers spaced apart from each other. The gate insulating layer GI may have a stacked structure in which a plurality of ferroelectric material layers and a plurality of paraelectric material layers are alternately stacked.

The gate electrode GE may include a first metal pattern and a second metal pattern on the first metal pattern. The first metal pattern may be provided on the gate insulating layer GI and adjacent to the first, second, and third semiconductor patterns SP1, SP2, and SP3. The first metal pattern may include a work function metal that adjusts a threshold voltage of a transistor. The desired threshold voltage of the transistor may be achieved by adjusting a thickness and composition of the first metal pattern. For example, the first, second, and third portions PO1, PO2, and PO3 of the gate electrode GE may include the first metal pattern that is a work function metal.

The first metal pattern may include a metal nitride layer. For example, the first metal pattern may include nitrogen (N) and at least one metal selected from the group consisting of titanium (Ti), tantalum (Ta), aluminum (Al), tungsten (W), and molybdenum (Mo). Furthermore, the first metal pattern may further include carbon (C). The first metal pattern may include a plurality of work function metal layers which are stacked.

The second metal pattern may include a metal with lower resistance than the first metal pattern. For example, the second metal pattern may include at least one metal selected from the group consisting of tungsten (W), aluminum (Al), titanium (Ti), and tantalum (Ta). For example, the fourth portion PO4 of the gate electrode GE may include the first metal pattern and the second metal pattern on the first metal pattern.

A first interlayer insulating layer 110 may be provided on the substrate 100. The first interlayer insulating layer 110 may be on (e.g., cover or overlap) the gate spacers GS and the first and second source/drain patterns SD1 and SD2. An upper (e.g., the uppermost) surface of the first interlayer insulating layer 110 may be (substantially) coplanar with an upper (e.g., the uppermost) surface of the gate capping pattern GP and an upper (e.g., the uppermost) surface of the gate spacer GS. A second interlayer insulating layer 120 may be disposed on the first interlayer insulating layer 110 and the gate capping pattern GP. The second interlayer insulating layer 120 may cover (overlap) the gate capping pattern GP. A third interlayer insulating layer 130 may be provided on the second interlayer insulating layer 120. A fourth interlayer insulating layer 140 may be provided on the third interlayer insulating layer 130. As an example, the first to fourth interlayer insulating layers 110 to 140 may each include a silicon oxide layer.

The single height cell SHC may have a first boundary BD1 and a second boundary BD2 facing each other in the second direction D2. The first and second boundaries BD1 and BD2 may extend in the first direction D1. The single height cell SHC may have a third boundary BD3 and a fourth boundary BD4 facing each other in the first direction D1. The third and fourth boundaries BD3 and BD4 may extend in the second direction D2.

A pair of separation structures DB facing each other in the second direction D2 may be provided on both sides of the single height cell SHC. For example, the pair of separation structures DB may be provided on the first and second boundaries BD1 and BD2 of the single height cell SHC, respectively. The separation structure DB may extend parallel to the gate electrodes GE in the first direction D1. A pitch between the separation structure DB and the gate electrode GE adjacent thereto may be the same as the first pitch.

The separation structure DB may extend in (e.g., penetrate) the first and second interlayer insulating layers 110 and 120 and (e.g., extend into) the first and second active patterns AP1 and AP2. The separation structure DB may extend in the upper portion of each of the first and second active patterns AP1 and AP2. The isolation structure DB may electrically separate an active region (e.g., the first and second active regions AR1 and AR2) of the single height cell SHC from active regions of other adjacent cells.

Active contacts AC extending in (e.g., penetrating) first and second interlayer insulating layers 110 and 120 and electrically connected to the first and second source/drain patterns SD1 and SD2, respectively, may be provided. A pair of active contacts AC may be provided on both sides of the gate electrode GE, respectively. For example, the pair of active contacts AC may be separated by the gate electrode GE. In a plan view, the active contact AC may have a bar shape extending in the first direction D1.

The active contact AC may be a self-aligned contact. In other words, the active contact AC may be formed in a self-aligned manner by using the gate capping pattern GP and the gate spacer GS. For example, the active contact AC may be on (e.g., cover or overlap) at least a part of the sidewall of the gate spacer GS. Although not shown, the active contact AC may be on (e.g., cover or overlap) a part of the top surface of the gate capping pattern GP.

A metal-semiconductor compound layer SC, for example, a silicide layer, may be disposed each between the active contact AC and the first source/drain pattern SD1 and between the active contact AC and the second source/drain pattern SD2. The active contact AC may be electrically connected to the source/drain patterns SD1 and SD2 through the metal-semiconductor compound layer SC. For example, the metal-semiconductor compound layer SC may include titanium-silicide, tantalum-silicide, tungsten-silicide, nickel-silicide, and/or cobalt-silicide.

Gate contacts GC extending in (e.g., penetrating) the second interlayer insulating layer 120 and the gate capping pattern GP and electrically connected to the gate electrodes GE, respectively, may be provided. In a plan view, the gate contacts GC may be disposed to overlap the first active region AR1 and the second active region AR2, respectively. As an example, the gate contact GC may be provided on the second active pattern AP2.

In some embodiments, referring to FIG. 5B, an upper portion of the active contact AC adjacent to the gate contact GC may be filled with an upper insulating pattern UIP. A lower (e.g., lowermost) surface of the upper insulating pattern UIP may be lower than a lower (e.g., lowermost) surface of the gate contact GC. In other words, the upper (e.g., uppermost) surface of the active contact AC adjacent to the gate contact GC may be lowered than the lower (e.g., lowermost) surface of the gate contact GC by the upper insulating pattern UIP. As a result, a short circuit may be reduced (e.g., prevented) from occurring when the gate contact GC contacts the active contact AC adjacent thereto.

Each of the active contact AC and the gate contact GC may include a conductive pattern FM and a barrier pattern BM extending around (e.g., at least partially surrounding) the conductive pattern FM. For example, the conductive pattern FM may include aluminum, copper, tungsten, molybdenum, and/or cobalt. The barrier pattern BM may be on (e.g., cover or overlap) sidewalls and lower (e.g., lowermost) surface of the conductive pattern FM. The barrier pattern BM may include a metal layer/metal nitride layer. The metal layer may include, for example, titanium, tantalum, tungsten, nickel, cobalt, and/or platinum. The metal nitride layer may include, for example, titanium nitride (TiN), tantalum nitride (TaN), tungsten nitride (WN), nickel nitride (NiN), cobalt nitride (CoN), and/or platinum nitride (PtN).

A first metal layer M1 may be provided in the third interlayer insulating layer 130. For example, the first metal layer M1 may include the first power wiring M1_R1, the second power wiring M1_R2, and first wirings M1_I. The first power wiring M1_R1, the second power wiring M1_R2, and first wirings M1_I of the first metal layer M1 may extend parallel to each other in the second direction D2.

Specifically, the first and second power wirings M1_R1 and M1_R2 may be provided on the third and fourth boundaries BD3 and BD4 of the single height cell SHC, respectively. The first power wiring M1_R1 may extend in the second direction D2 along the third boundary BD3. The second power wiring M1_R2 may extend in the second direction D2 along the fourth boundary BD4.

The first wirings M1_I of the first metal layer M1 may be disposed between the first and second power wirings M1_R1 and M1_R2. The first wirings M1_I of the first metal layer M1 may be disposed (e.g., arranged) in the first direction D1 at a second pitch. The second pitch may be less than the first pitch. A line width of each of the first wirings M1_I (in the first direction D1) may be less than a line width of each of the first and second power wirings M1_R1 and M1_R2 (in the first direction D1).

The first metal layer M1 may further include first vias VI1. The first vias VI1 may be provided below the first power wiring M1_R1, the second power wiring M1_R2, and the first wirings M1_I of the first metal layer M1, respectively. The active contact AC and at least one of the first power wiring M1_R1, the second power wiring M1_R2, and the first wirings M1_I of the first metal layer M1 may be electrically connected to each other through the first via VI1. The gate contact GC and at least one of the first power wiring M1_R1, the second power wiring M1_R2, and the first wirings M1_I of the first metal layer M1 may be electrically connected to each other through the first via VI1. For example, the first via VI1 may be between the gate contact GC and at least one of the first power wiring M1_R1, the second power wiring M1_R2, and the first wirings M1_1 of the first metal layer M1.

The first power wiring M1_R1, the second power wiring M1_R2, and the first wirings M1_I of the first metal layer M1 may be formed through separate processes from the first via VI1 therebelow. In other words, the first power wiring M1_R1, the second power wiring M1_R2, and the first wirings M1_I of the first metal layer M1 may be formed through a single damascene process, and the first via VI1 may be formed through a (another) single damascene process. The semiconductor device according to the embodiment may be formed using, for example, a process with a feature size of less than 20 nm.

The second metal layer M2 may be provided in the fourth interlayer insulating layer 140. The second metal layer M2 may include a plurality of second wirings M2_I. Each of the second wirings M2_I of the second metal layer M2 may have a line shape or a bar shape extending in the first direction D1. In other words, the second wirings M2_I may extend parallel to each other in the first direction D1.

The second metal layer M2 may further include second vias VI2 respectively provided below the second wirings M2_I. At least one of the first power wiring M1_R1, the second power wiring M1_R2, and the first wirings M1_I of the first metal layer M1 and at least one the second wirings M2_I of the second metal layer M2 may be electrically connected to each other through the second via VI2. For example, the second via VI2 may be between the second wirings M2_I of the second metal layer M2 and at least one of the first power wiring M1_R1, the second power wiring M1_R2, and the first wirings M1_I of the first metal layer M1. In some embodiments, the second wirings M2_I of the second metal layer M2 and the second via VI2 therebelow may be formed together through a dual damascene process.

The first power wiring M1_R1, the second power wiring M1_R2, and the first wirings M1_I of the first metal layer M1 and the second wirings M2_I of the second metal layer M2 may include the same or different conductive materials. For example, the first power wiring M1_R1, the second power wiring M1_R2, and the first wirings M1_I of the first metal layer M1 and the second wirings M2_I of the second metal layer M2 may each include aluminum, copper, tungsten, molybdenum, ruthenium, and/or cobalt. Although not shown, metal layers (e.g., M3, M4, M5 . . . ) stacked on the fourth interlayer insulating layer 140 may be additionally disposed. Each of the stacked metal layers may include wirings for routing between cells.

FIG. 7A is a cross-sectional view taken along line I-I′ of FIG. 6A according to some embodiments. FIG. 7B is a plan view taken along line II-II′ of FIG. 6A according to some embodiments. FIG. 7C is a plan view taken along line III-III′ of FIG. 6A according to some embodiments. The line II-II′ of FIG. 6A may be at a first vertical level LV1. The line III-III′ of FIG. 6B may be at a second vertical level LV2. The first vertical level LV1 may be the same as a vertical level of the second semiconductor pattern SP2. The second vertical level LV2 may be the same as a vertical level of the second portion PO2 of the gate electrode GE.

Hereinafter, the description with reference to FIG. 7A may relate to a cross-sectional view.

Referring to FIG. 7A, the protection pattern PTP may be on (e.g., cover or overlap) an upper (e.g., the uppermost) surface of the third semiconductor pattern SP3. The protection pattern PTP may extend on the upper surface of the uppermost semiconductor pattern among the plurality of semiconductor patterns. The protection pattern PTP may extend along the first sidewalls SW1 of each of the first to third semiconductor patterns SP1 to SP3. The protection pattern PTP may be on (e.g., cover or overlap) the first sidewalls SW1 of each of the first to third semiconductor patterns SP1 to SP3. The protection pattern PTP may be on (e.g., cover or overlap) a sidewall of the second epitaxial pattern EP2 (in the first direction D1). The protection pattern PTP may extend in the first direction D1 along an upper (e.g., the uppermost) surface of the device isolation layer ST.

Hereinafter, the description with reference to FIG. 7B may relate to a plan view, unless otherwise specified.

Referring to FIG. 7B, the second epitaxial pattern EP2 may be disposed between the first epitaxial pattern EP1 and the second semiconductor pattern SP2 and between the first epitaxial pattern EP1 and the protection pattern PTP. The first epitaxial pattern EP1 and the second epitaxial pattern EP2 may contact to each other. The first epitaxial pattern EP1 may be spaced apart from the protection pattern PTP in the second direction D2 with the second epitaxial pattern EP2 disposed therebetween. The second epitaxial pattern EP2 may contact the protection pattern PTP and the second sidewalls SW2 of the second semiconductor pattern SP2.

The second epitaxial pattern EP2 may include a source/drain center portion CEN and a source/drain edge portion EDG. The source/drain center portion CEN may be a central portion of the second epitaxial pattern EP2 in the first direction D1. The source/drain edge portion EDG may be disposed at an edge of the source/drain center portion CEN in the first direction D1. The source/drain edge portion EDG may contact the sidewall of the protection pattern PTP in the second direction D2. The first epitaxial pattern EP1 and the protection pattern PTP may be spaced apart from each other in the second direction D2 with the source/drain edge portion EDG disposed therebetween. Referring to FIG. 7B, for example, the source/drain edge portion EDG may (entirely) overlap the protection pattern PTP in the second direction D2, and the source/drain center portion CEN may not overlap the protection pattern PTP in the second direction D2. The source/drain edge portion EDG and the source/drain center portion CEN of the second epitaxial pattern EP2 may form a unitary structure. A unitary structure herein may refer to a structure without a visible boundary between two sub-elements thereof.

The protection pattern PTP may be spaced apart from the fourth portion PO4 in the second direction D2 with the gate insulating layer GI disposed therebetween. Referring to FIGS. 7A and 7B, the gate spacer GS may be on (e.g., cover or overlap) an upper (e.g., the uppermost) surface of the protection pattern PTP and sidewall thereof (in the first direction D1). A width of the gate spacer GS in the second direction D2 and a width of the protection pattern PTP in the second direction D2 may be (substantially) the same as each other. In the specification, the term “substantially the same” may be a concept including not only mathematical sameness, but also a process margin of error.

Referring again to FIG. 7B, the second semiconductor pattern SP2 may have a first width W1 in the first direction D1. The second epitaxial pattern EP2 may have a second width W2 in the first direction D1. The second width W2 may be greater than the first width W1. This may be due to the fact that when the second epitaxial pattern EP2 is formed through the SEG process, the second epitaxial pattern EP2 is formed not only from the second semiconductor pattern SP2 but also from the protection pattern PTP.

The source/drain center portion CEN of the second epitaxial pattern EP2 may have a third width W3 in the second direction D2 at an arbitrary point. The source/drain edge portion EDG of the second epitaxial pattern EP2 may have a fourth width W4 in the second direction D2 at an arbitrary point. The fourth width W4 may be less than the third width W3. For example, the greatest fourth width W4 may be the same as or less than the narrowest third width W3. The third width W3 and the fourth width W4 of the second epitaxial pattern EP2 may be at the same vertical level (e.g., at the first vertical level LV1).

The first epitaxial pattern EP1 may include a high concentration of silicon-germanium. The concentration of germanium in the first epitaxial pattern EP1 may be, for example, about 10 at % to about 30 at %. The second epitaxial pattern EP2 may include silicon or a low concentration of silicon-germanium. When the second epitaxial pattern EP2 includes the low concentration of silicon-germanium, the concentration of germanium in the second epitaxial pattern EP2 may be, for example, greater than 0 at % and about 10 at % or less. The second epitaxial pattern EP2 may further include, for example, phosphorus (P), boron (B), carbon (C), and/or arsenic (As).

The protection pattern PTP may include a material having etch selectivity with the first epitaxial pattern EP1. The protection pattern PTP may include, for example, silicon or a low concentration of silicon-germanium. When the protection pattern PTP includes the low concentration of silicon-germanium, the concentration of germanium in the protection pattern PTP may be, for example, greater than 0 at % and about 10 at % or less. The protection pattern PTP may further include, for example, phosphorus (P), boron (B), carbon (C), arsenic (As), indium (In), and/or gallium (Ga). As described above, the description of relationships between the second semiconductor pattern SP2 and the protection pattern PTP, between the second semiconductor pattern SP2 and the first epitaxial pattern EP1, and between the second semiconductor pattern SP2 and the second epitaxial pattern EP2 may also be similarly (e.g., identically) applied to relationships between each of the first and third semiconductor patterns SP1 and SP3 and the protection pattern PTP, between each of the first and third semiconductor patterns SP1 and SP3 and the first epitaxial pattern EP1, and between each of the first and third semiconductor patterns SP1 and SP3 and the second epitaxial pattern EP2. That is, a plan view at the same vertical level as the vertical level of the first semiconductor pattern SP1 or the third semiconductor pattern SP3, rather than the first vertical level LV1, may also be (substantially) the same as FIG. 7B, except for the second semiconductor pattern SP2.

Hereinafter, the description with reference to FIG. 7C may relate to a plan view, unless otherwise specified.

Referring to FIG. 7C, the second epitaxial pattern EP2 may be disposed between the first epitaxial pattern EP1 and the second portion PO2 and between the first epitaxial pattern EP1 and the protection pattern PTP. The first epitaxial pattern EP1 may be spaced apart from the protection pattern PTP in the second direction D2 with the second epitaxial pattern EP2 disposed therebetween. The second epitaxial pattern EP2 may contact the protection pattern PTP and may be spaced apart from sidewalls of the second portion PO2 in the second direction D2. The gate insulating layer GI may be disposed between the second epitaxial pattern EP2 and the second portion PO2.

The source/drain center portion CEN of the second epitaxial pattern EP2 may have a fifth width W5 in the second direction D2 at an arbitrary point. The source/drain edge portion EDG of the second epitaxial pattern EP2 may have a sixth width W6 in the second direction D2 at an arbitrary point. The fifth width W5 may be greater than the third width W3, and the sixth width W6 may be greater than the fourth width W4. The fifth width W5 may be greater than the sixth width W6. Both the fifth width W5 and the sixth width W6 may be widths of the second epitaxial pattern EP2 at the second vertical level LV2. Referring to FIG. 7C, for example, the source/drain edge portion EDG may (entirely) overlap the protection pattern PTP in the second direction D2, and the source/drain center portion CEN may not overlap the protection pattern PTP in the second direction D2. The source/drain edge portion EDG and the source/drain center portion CEN of the second epitaxial pattern EP2 may form a unitary structure. A unitary structure herein may refer to a structure without a visible boundary between two sub-elements thereof. For example, the greatest sixth width W6 may be the same as or less than the narrowest fifth width W5.

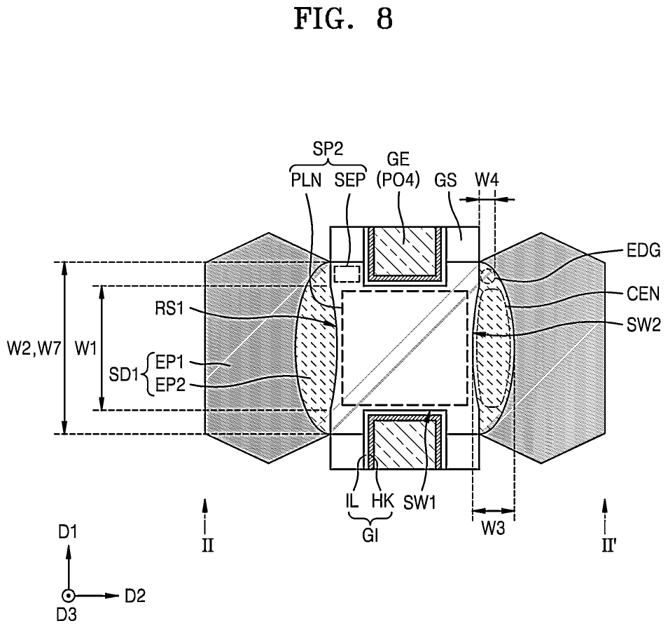

FIG. 8 is a plan view taken along line II-II′ of FIG. 6A according to some embodiment. Hereinafter, redundant descriptions given with reference to FIG. 7B may be omitted, and the differences may be described in detail.

Referring to FIG. 8, when the protection pattern PTP of FIG. 7B includes silicon, a boundary may not be observed (e.g., not be visually observed) between the second semiconductor pattern SP2 and the protection pattern PTP of FIG. 7B. That is, the protection pattern PTP of FIG. 7B may be observed as a part of the second semiconductor pattern SP2 (without a visible boundary therebetween), which is shown in the plan view of FIG. 8.

The second semiconductor pattern SP2 may include a semiconductor pattern center portion PLN and a semiconductor pattern protrusion portion SEP. A position and shape of the semiconductor pattern center portion PLN may be (substantially) the same as a position and shape of the second semiconductor pattern SP2 of FIG. 7B. A position and shape of the semiconductor pattern protrusion portion SEP may be (substantially) the same as a position and shape of the protection pattern PTP of FIG. 7B. The semiconductor pattern center portion PLN may be disposed at the central region of the second semiconductor pattern SP2 in the first direction D1. The semiconductor pattern protrusion portion SEP may protrude from the corner of the semiconductor pattern center portion PLN in the first direction D1. Referring to FIGS. 7A and 8, the semiconductor pattern protrusion portion SEP may extend in the third direction D3 like the protection pattern PTP of FIG. 7A. The semiconductor pattern protrusion portion SEP may extend to (or on) an upper (e.g., the uppermost) surface of the third semiconductor pattern SP3.

Referring again to FIG. 8, the semiconductor pattern center portion PLN may have the first sidewalls SW1 and the second sidewalls SW2 as in FIG. 7B. The second sidewalls SW2 of the semiconductor pattern center portion PLN may contact the second epitaxial pattern EP2. The semiconductor pattern protrusion portion SEP may be formed integrally with the semiconductor pattern center portion PLN. For example, the semiconductor pattern protrusion portion SEP and the semiconductor pattern center portion PLN may form a unitary structure. A sidewall of the semiconductor pattern protrusion portion SEP in the second direction D2 may contact the second epitaxial pattern EP2.

The semiconductor pattern center portion PLN may have the first width W1 of FIG. 7B in the first direction D1. The maximum width of the second semiconductor pattern SP2 in the first direction D1 may be a seventh width W7. The seventh width W7 may be (substantially) the same as the second width W2 (e.g., the second width W2 in FIG. 7B).

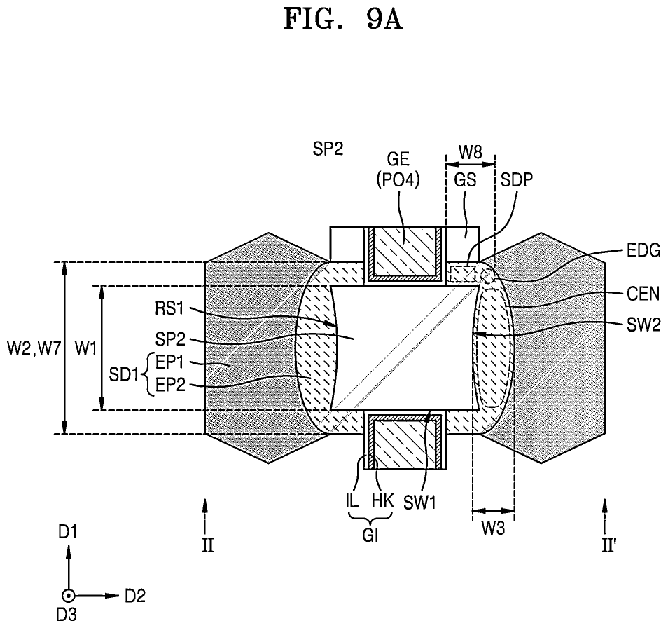

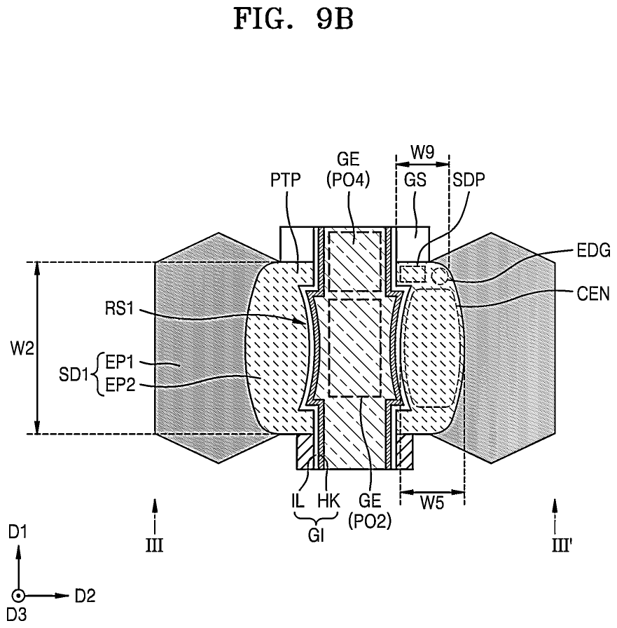

FIG. 9A is a plan view taken along line II-II′ of FIG. 6A according to some embodiments. FIG. 9B is a plan view taken along line III-III′ of FIG. 6A according to some embodiments. Hereinafter, redundant descriptions given with reference to FIGS. 7B and 7C may be omitted, and the differences may be described in detail.

Referring to FIGS. 9A and 9B, when the protection pattern PTP of FIG. 7B includes a low concentration of silicon-germanium, a boundary may not be observed (e.g., not be visually observed) between the second epitaxial pattern EP2 and the protection pattern PTP of FIG. 7B. The second epitaxial pattern EP2 and the protection pattern PTP of FIG. 7B may be integrally formed. For example, the second epitaxial pattern EP2 and the protection pattern PTP may form a unitary structure. That is, the protection pattern PTP of FIG. 7B may be observed as a part of the second epitaxial pattern EP2 (without a visible boundary therebetween), which are shown in the plan views of FIGS. 9A and 9B. The part of the second epitaxial pattern EP2 may be a source/drain protrusion portion SDP, which will be described below.

The second epitaxial pattern EP2 may include the source/drain center portion CEN, the source/drain edge portion EDG, and the source/drain protrusion portion SDP. The source/drain protrusion portion SDP may protrude from the source/drain edge portion EDG in the second direction D2. Due to the source/drain center portion CEN, the source/drain edge portion EDG, and the source/drain protrusion portion SDP, the second epitaxial pattern EP2 may have a “[” or “]” shape. Referring to FIG. 9A, for example, the source/drain edge portion EDG may (entirely) overlap the source/drain protrusion portion SDP in the second direction D2, and the source/drain center portion CEN may not overlap the source/drain protrusion portion SDP in the second direction D2. The source/drain protrusion portion SDP may (entirely) overlap the second semiconductor pattern SP2 in the first direction D1, and the source/drain edge portion EDG may not overlap the second semiconductor pattern SP2 in the first direction D1. The second epitaxial pattern EP2 may contact the first and second sidewalls SW1 and SW2 of the second semiconductor pattern SP2. Likewise, the second epitaxial pattern EP2 may also contact sidewalls of the first semiconductor pattern SP1 and the third semiconductor pattern SP3 in the first and second directions D1 and D2. Referring to FIGS. 7A, 9A, and 9B, the source/drain protrusion portion SDP may extend in the third direction D3 like the protection pattern PTP of FIG. 7A. The source/drain protrusion portion SDP may extend to (or on) an upper (e.g., the uppermost) surface of the third semiconductor pattern SP3.

Referring again to FIGS. 9A and 9B, the second epitaxial pattern EP2 may have an eighth width W8 and a ninth width W9. The eighth width W8 may be the maximum width of the second epitaxial pattern EP2 in the second direction D2 at the first vertical level LV1. The eighth width W8 may include widths of the source/drain protrusion portion SDP and the source/drain edge portion EDG in the second direction D2 at the first vertical level LV1. The ninth width W9 may be the maximum width of the second epitaxial pattern EP2 in the second direction D2 at the second vertical level LV2. The nineth width W9 may include widths of the source/drain protrusion portion SDP and the source/drain edge portion EDG in the second direction D2 at the second vertical level LV2. The eighth width W8 may be greater than the third width W3. The ninth width W9 may be greater than the fifth width W5. A sidewall of the source/drain protrusion portion SDP in the second direction D2 may be more adjacent (closer) to the gate electrode GE than a sidewall of the source/drain center portion CEN in the second direction D2. For example, the closest sidewall portion of the source/drain protrusion portion SDP to the gate electrode GE in the second direction D2 may be closer to the gate electrode GE in the second direction D2 than the closest sidewall portion of the source/drain center portion CEN to the gate electrode GE in the second direction D2.

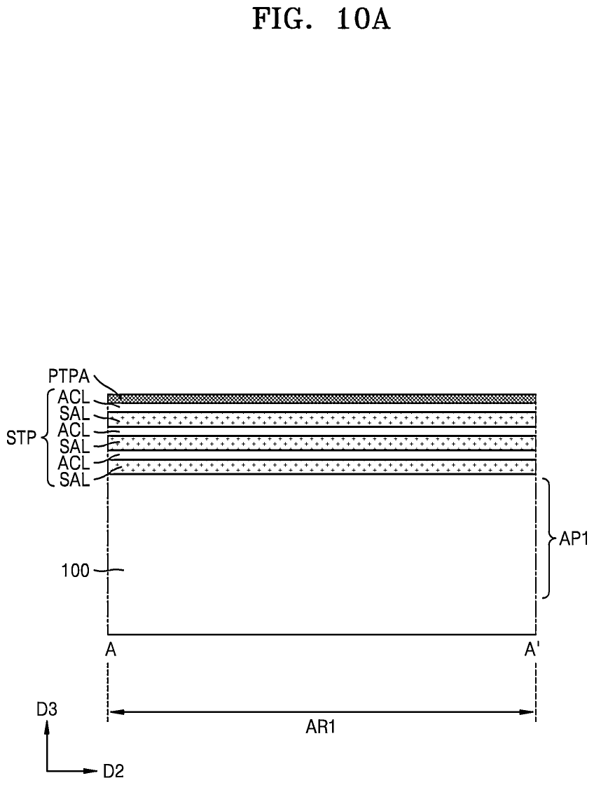

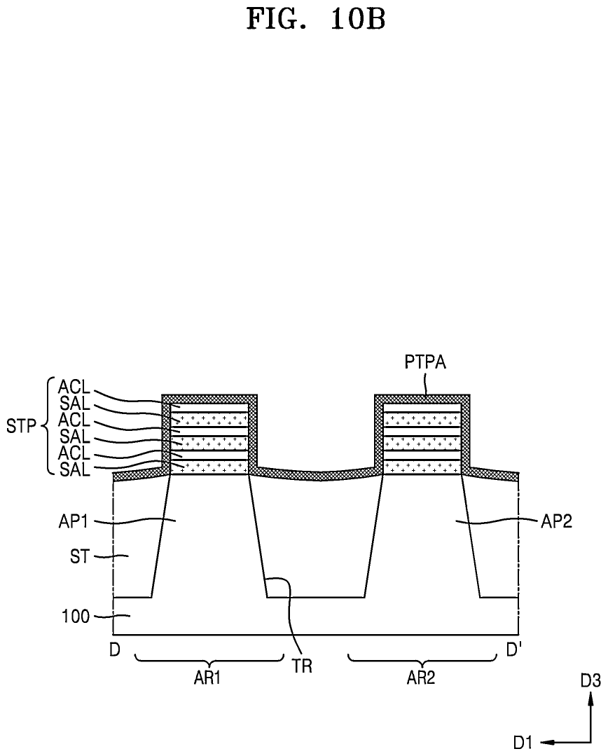

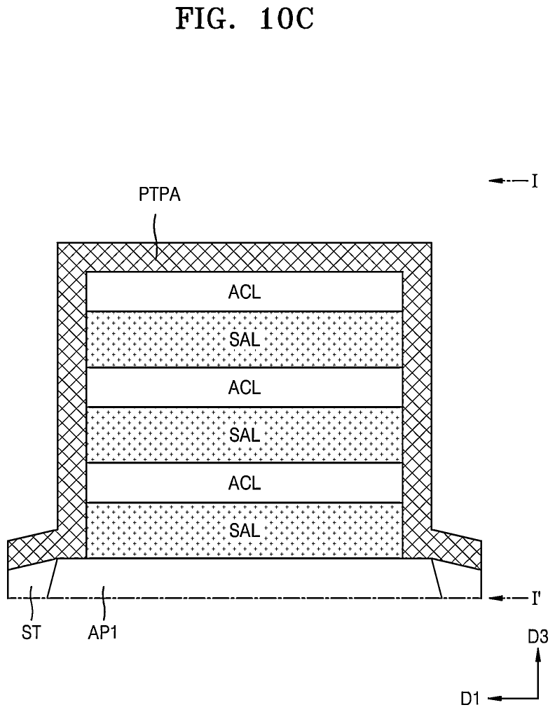

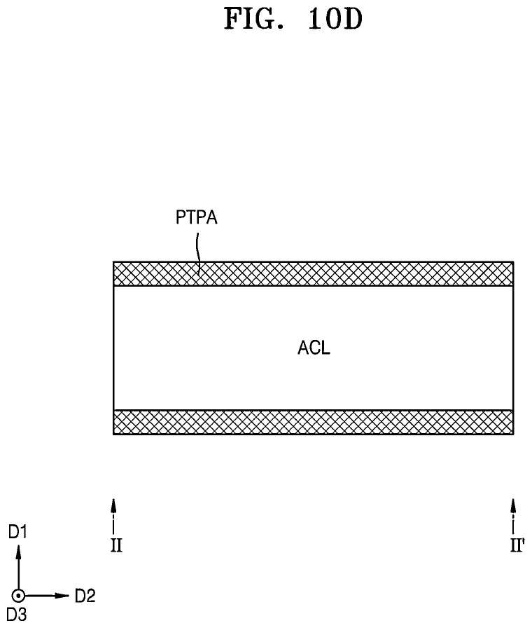

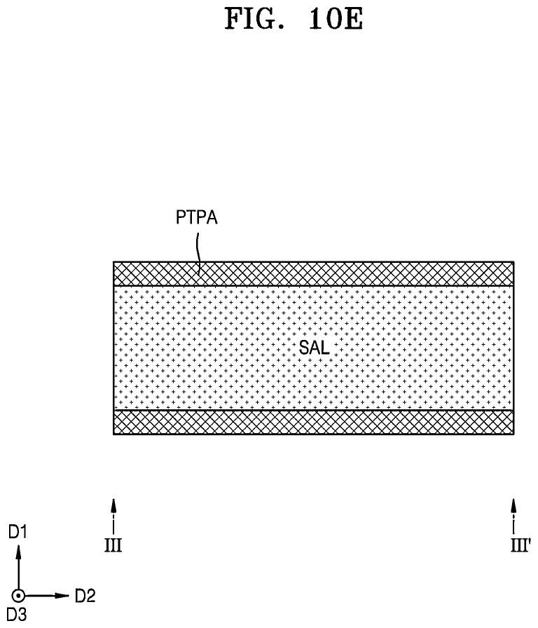

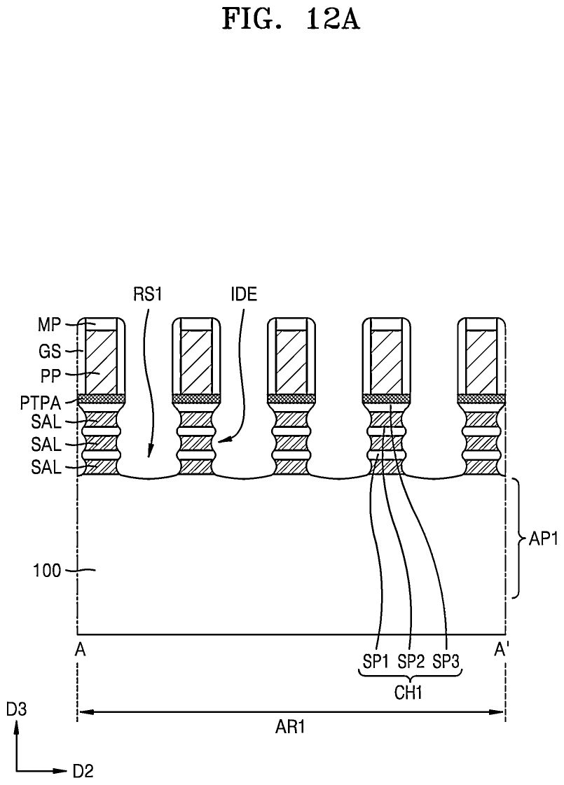

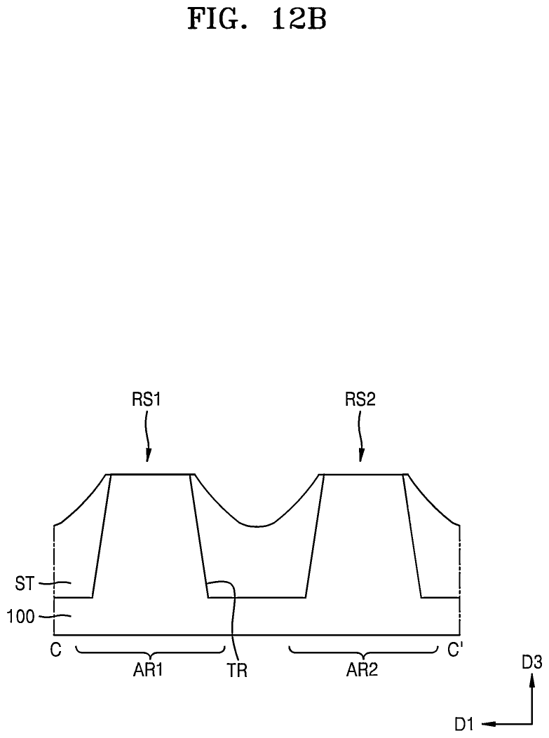

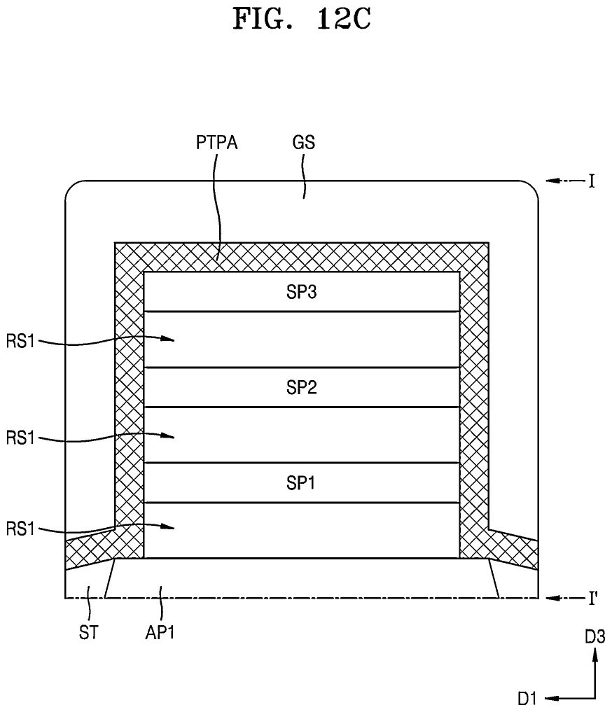

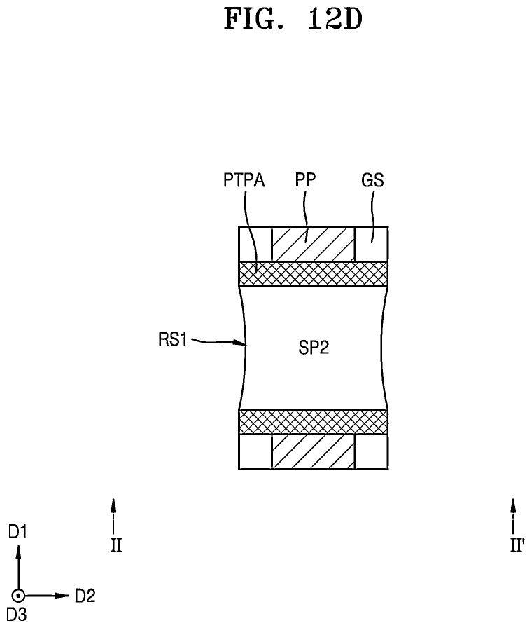

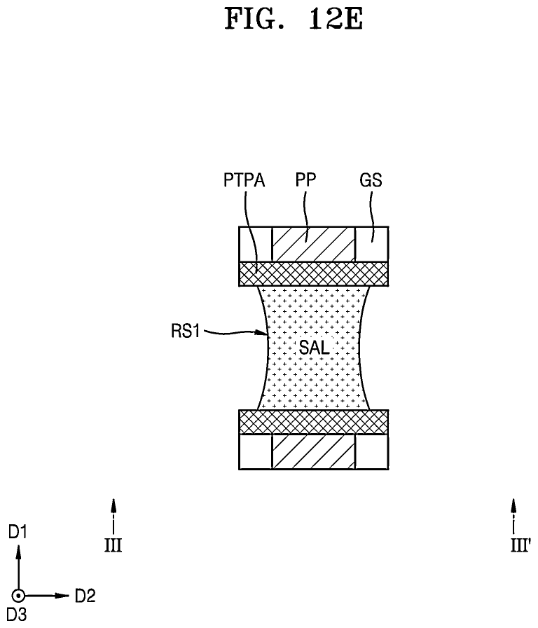

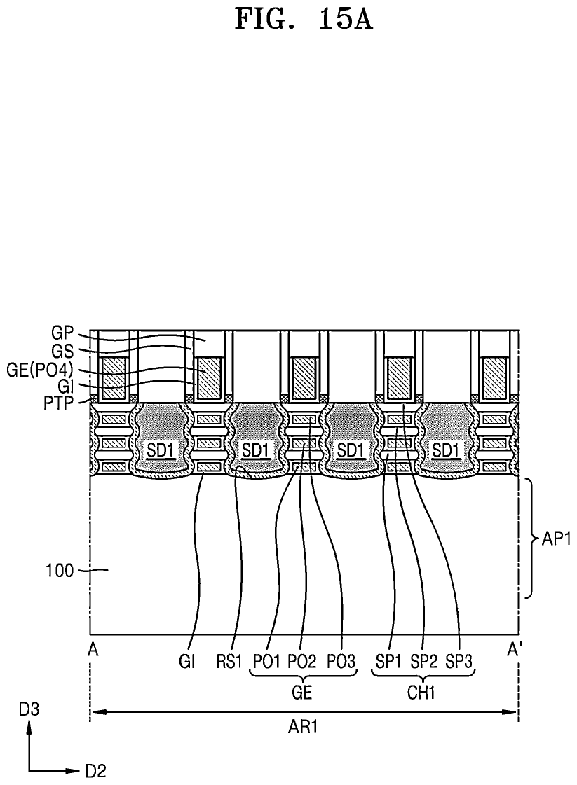

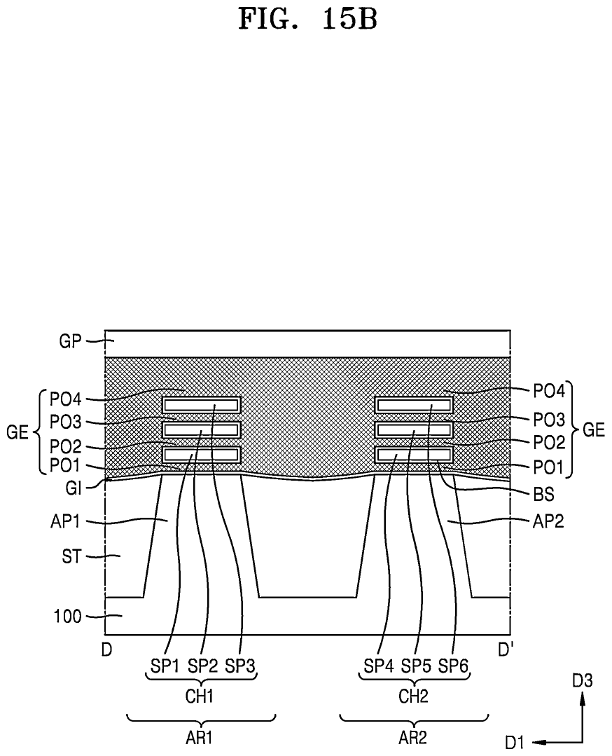

FIGS. 10A to 15B are cross-sectional views for explaining a method of manufacturing a semiconductor device according to some embodiments. Specifically, FIGS. 10A, 11A, 12A, 13A, 14A, and 15A are cross-sectional views corresponding to line A-A′ in FIG. 4. FIGS. 12B, 13B, and 14B are cross-sectional views corresponding to line C-C′ in FIG. 4. FIGS. 10B, 11B, 14C, and 15B are cross-sectional views corresponding to line D-D′ in FIG. 4. FIGS. 10C, 11C, 12C, and 13C are cross-sectional views taken along line I-I′ of FIG. 6A. FIGS. 10D, 11D, 12D, 13D, and 14D are cross-sectional views taken along line II-II′ of FIG. 6A. FIGS. 10E, 11E, 12E, 13E, and 14E are cross-sectional views taken along line III-III′ of FIG. 6A.

Referring to FIGS. 10A to 10E, a substrate 100 including the first and second active regions AR1 and AR2 may be provided. Active layers ACL and sacrificial layers SAL which are alternately stacked may be formed on the substrate 100. The active layers ACL may include, for example, one of silicon, germanium, and silicon-germanium, and the sacrificial layers SAL may include the other one of silicon, germanium, and silicon-germanium.

The sacrificial layer SAL may include a material that may have an etch selectivity with respect to the active layer ACL. For example, the active layers ACL may include silicon, and the sacrificial layers SAL may include silicon-germanium. The concentration of germanium in each of the sacrificial layers SAL may be about 10 at % to about 30 at %.

Mask patterns may be formed on the first and second active regions ARI and AR2 of the substrate 100, respectively. The mask pattern may have a line shape or a bar shape extending in the second direction D2.

The trench TR may be formed by performing a patterning process using the mask patterns as an etch mask. The device isolation layer ST, which will be formed in the trench TR in the following processes, may define the first active pattern AP1 and the second active pattern AP2. In some embodiments, the first active pattern AP1 and the second active pattern AP2 may be adjacent the device isolation layer ST. For example, the device isolation layer ST may be between the first active pattern AP1 and the second active pattern AP2 in the first direction D1. The first active pattern AP1 may be formed on (or in) the first active region AR1. The second active pattern AP2 may be formed on (or in) the second active region AR2.

Stack patterns STP may be formed on each of the first and second active patterns AP1 and AP2. The stack patterns STP may include the active layers ACL and the sacrificial layers SAL which are alternately stacked with each other. The stack patterns STP may be formed together with the first and second active patterns AP1 and AP2 during the patterning process.

The device isolation layer ST that at least partially fills the trench TR may be formed. Specifically, an insulating layer on (e.g., covering or overlapping) the first and second active patterns AP1 and AP2 and the stack patterns STP may be formed on the entire surface of the substrate 100. The device isolation layer ST may be formed by recessing the insulating layer until (an upper surface and sidewalls of) the stack patterns STP are exposed.

The device isolation layer ST may include an insulating material such as a silicon oxide layer. The stack patterns STP may be exposed on the device isolation layer ST. In other words, the stack patterns STP may protrude vertically above the device isolation layer ST.

A protection pattern layer PTPA on (e.g., covering or overlapping) the device isolation layer ST and the stack patterns STP may be formed. The protection pattern layer PTPA may be formed over (on) the entire surface of the substrate 100. The protection pattern layer PTPA may be formed using chemical vapor deposition (CVD), physical vapor deposition (PVD), atomic layer deposition (ALD), and/or a combination thereof. The protection pattern layer PTPA may include a material having etch selectivity with the sacrificial layers SAL. The protection pattern layer PTPA may include, for example, silicon or a low concentration of silicon-germanium. When the protection pattern layer PTPA includes the low concentration of silicon-germanium, the concentration of germanium may be, for example, greater than 0 at % and about 10 at % or less.

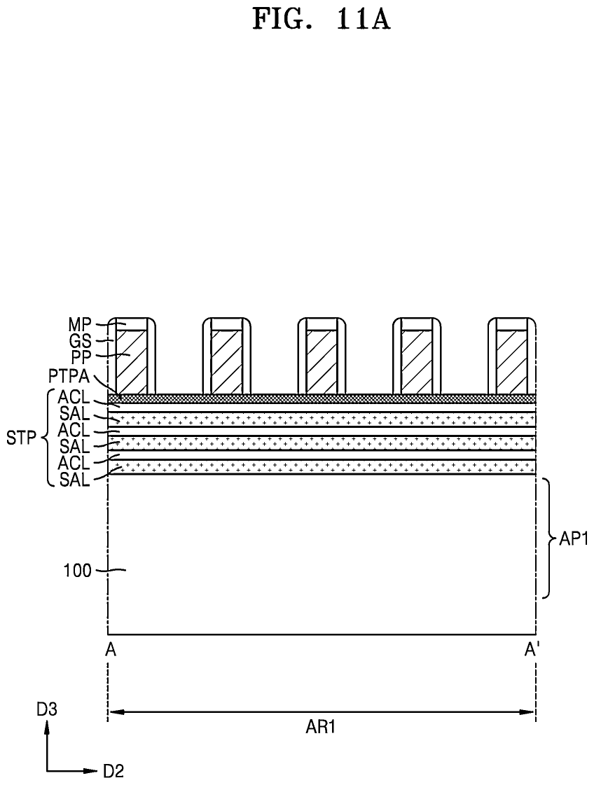

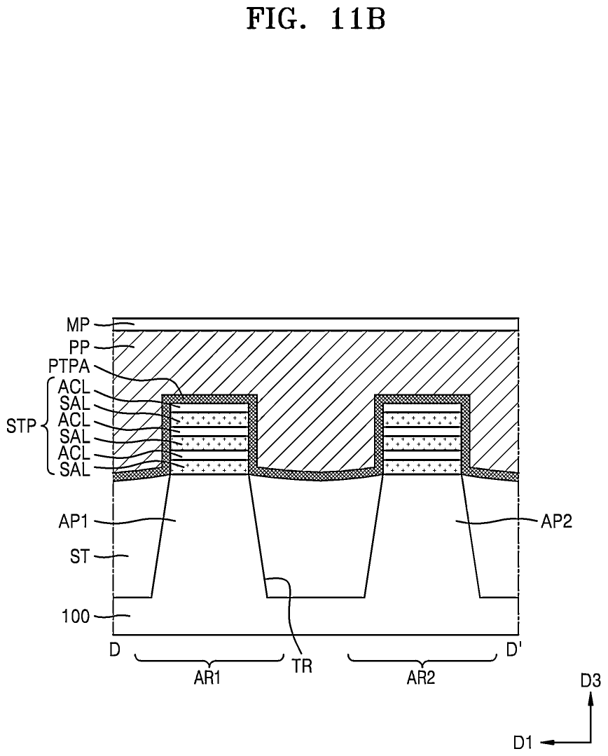

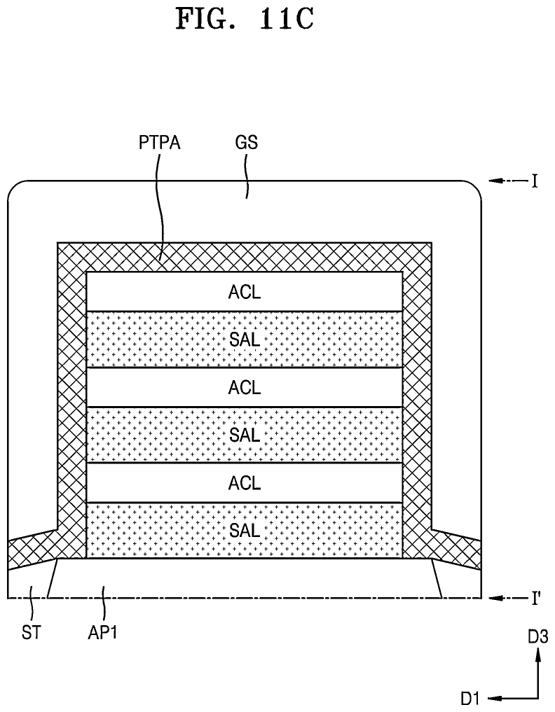

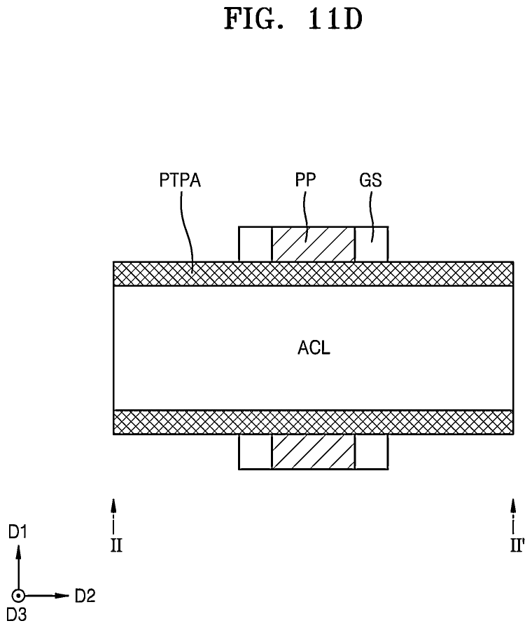

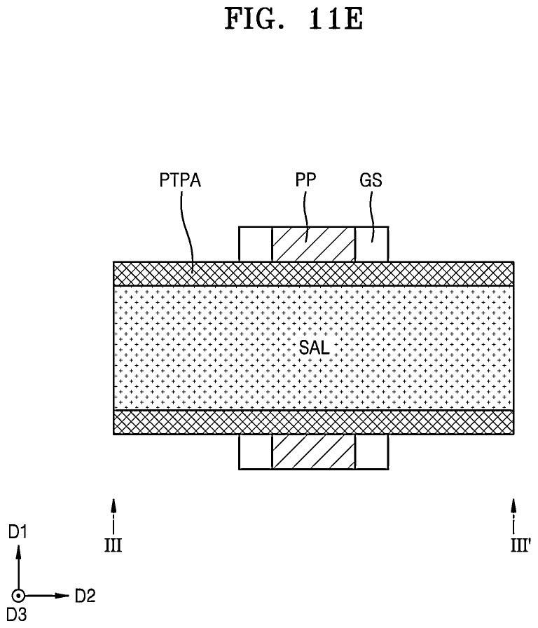

Referring to FIGS. 10B, 11A, and 11E, sacrificial patterns PP may be formed across the stack patterns STP on the substrate 100. Each of the sacrificial patterns PP may be formed in a line shape or a bar shape extending in the first direction D1. The sacrificial patterns PP may be arranged in the second direction D2 at a first pitch. The sacrificial patterns PP may be formed on the protection pattern layer PTPA.

Specifically, forming the sacrificial patterns PP may include forming a sacrificial layer on the entire surface of the substrate 100, forming hard mask patterns MP on the sacrificial layer, and patterning the sacrificial layer using the hard mask patterns MP as an etch mask. The sacrificial layer may include, for example, polysilicon.

A pair of gate spacers GS may be formed on both sidewalls of each of the sacrificial patterns PP. Forming the gate spacers GS may include conformally forming a gate spacer layer on the entire surface of the substrate 100 and anisotropically etching the gate spacer layer. In some embodiments, the gate spacer GS may be a multi-layer including at least two layers.

Referring to FIGS. 11B and 12A to 12E, first recesses RS1 may be formed in the stack pattern STP on the first active pattern AP1. Although not shown, second recesses RS2 may be formed in the stack pattern STP on the second active pattern AP2. While forming the first and second recesses RS1 and RS2, the device isolation layer ST on both sides of the first and second active patterns AP1 and AP2 may be further recessed.

Specifically, the first recesses RS1 may be formed by etching the stack pattern STP on the first active pattern AP1 using the hard mask patterns MP and the gate spacers GS as an etch mask. The first recess RS1 may be formed between a pair of (adjacent) sacrificial patterns PP. Forming the first recess RS1 may include additionally performing a selective etching process on the exposed sacrificial layers SAL. Each of the sacrificial layers SAL may be indented through the selective etching process to form an indented region IDE. Accordingly, the first recess RS1 may have a wavy (uneven) inner sidewall. The second recesses RS2 in the stack pattern STP on the second active pattern AP2 may be formed in the same manner as the first recesses RS1.

As the first recesses RS1 are formed, a part of the protection pattern layer PTPA between the pair of (adjacent) sacrificial patterns PP may be removed. At this time, a part of the protection pattern layer PTPA that vertically overlaps the sacrificial patterns PP and a part of the protection pattern layer PTPA that vertically overlaps the gate spacers GS may not be removed. That is, the remaining protection pattern layer PTPA may (vertically) overlap the sacrificial patterns PP and the gate spacers GS (in the third direction D3).

The first, second, and third semiconductor patterns SP1, SP2, and SP3 sequentially stacked between the first recesses RS1 adjacent to each other may be formed from the active layers ACL, respectively. The first, second, and third semiconductor patterns SP1, SP2, and SP3 between the first recesses RS1 adjacent to each other may form the first channel pattern CH1. The first, second, and third semiconductor patterns SP1, SP2, and SP3 between the second recesses RS2 adjacent to each other may form the second channel pattern CH2.

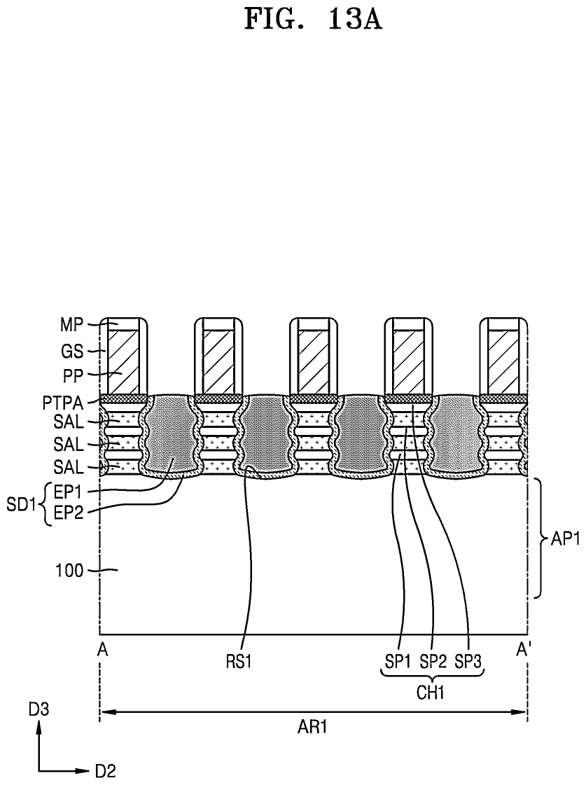

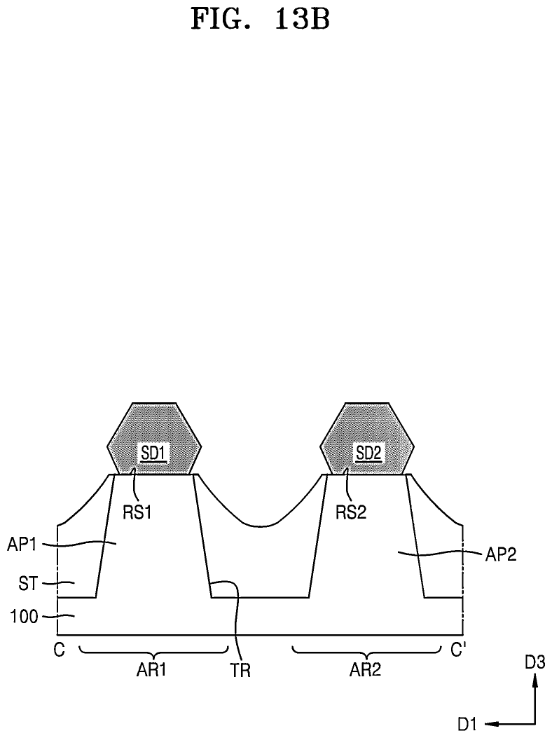

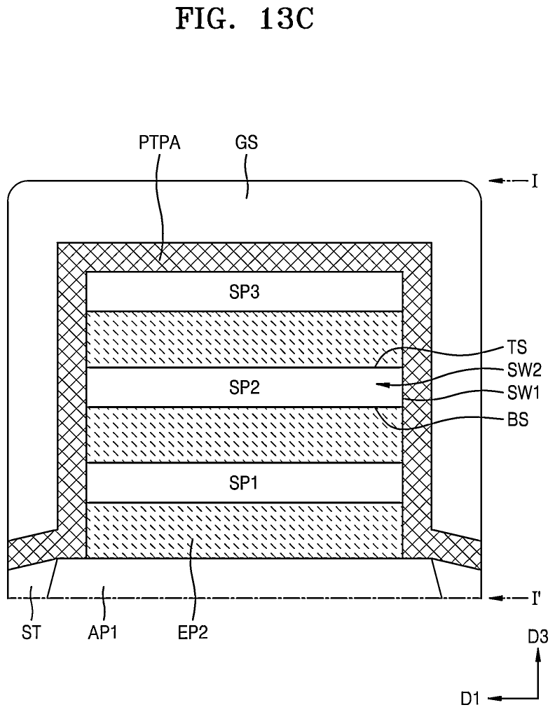

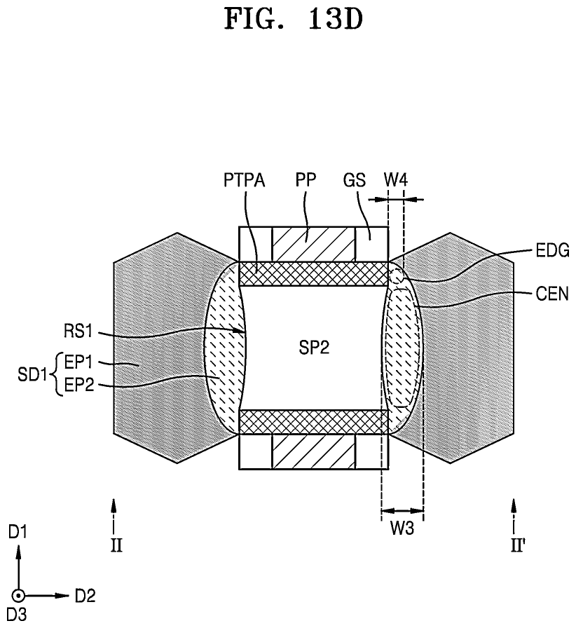

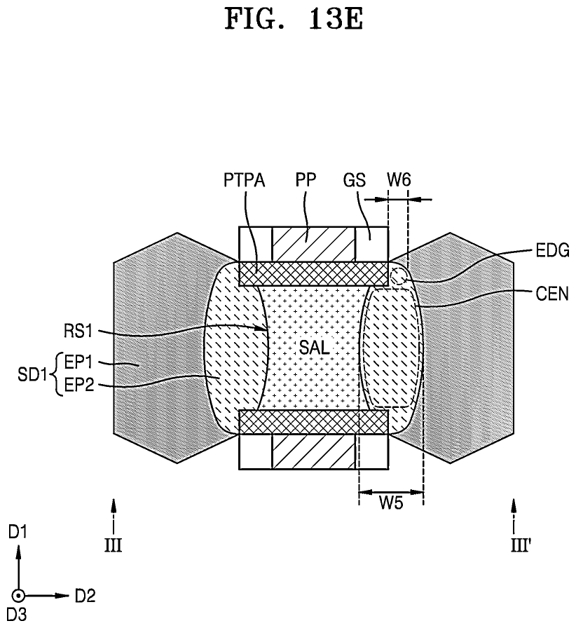

Referring to FIGS. 11B and 13A to 13E, the first source/drain patterns SD1 may be formed in the first recesses RS1, respectively. Specifically, the second epitaxial pattern EP2 of the first source/drain pattern SD1 may be formed by performing the SEG process using an inner wall of the first recess RS1 as a seed layer. The second epitaxial pattern EP2 may fill a part of the first recess RS1. The second epitaxial pattern EP2 of the first source/drain pattern SD1 may be grown using, as a seed layer, the first, second, and third semiconductor patterns SP1, SP2, and SP3 exposed by the first recess RS1 and the substrate 100. Subsequently, the first epitaxial pattern EP1 of the first source/drain pattern SD1 may be formed by performing the SEG process using an inner wall of the second epitaxial pattern EP2 of the first source/drain pattern SD1 as a seed layer. As a result, the first source/drain patterns SD1 may be formed. As an example, the SEG process may include a CVD process and/or a molecular beam epitaxy (MBE) process.

The second epitaxial pattern EP2 of the first source/drain pattern SD1 may include the source/drain center portion CEN and the source/drain edge portion EDG. The descriptions of the source/drain center portion CEN and the source/drain edge portion EDG are the same as the descriptions of the source/drain center portion CEN and the source/drain edge portion EDG given with reference to FIGS. 7B and 7C. At the first vertical level LV1 of FIG. 6A, the source/drain center portion CEN may have the third width W3 in the second direction D2 at an arbitrary point. The source/drain edge portion EDG may have the fourth width W4 in the second direction D2 at an arbitrary point. The fourth width W4 may be less than the third width W3. At the second vertical level LV2 of FIG. 6A, the source/drain center portion CEN may have the fifth width W5 in the second direction D2 at an arbitrary point. The source/drain edge portion EDG may have the sixth width W6 in the second direction D2 at an arbitrary point. The sixth width W6 may be less than the fifth width W5.

In an embodiment, the first source/drain pattern SD1 may include the same semiconductor element (e.g., Si) as the substrate 100. While the first source/drain pattern SD1 is formed, impurities (e.g., phosphorus, arsenic, and/or antimony) that cause the first source/drain pattern SD1 to be n-type may be in-situ injected. As another example, after the first source/drain pattern SD1 is formed, impurities may be injected into the first source/drain pattern SD1.

The second source/drain patterns SD2 may be formed in the second recesses RS2, respectively. Specifically, the second epitaxial pattern EP2 of the second source/drain pattern SD2 may be formed by performing the SEG process using the inner wall of the second recess RS2 as a seed layer. The first epitaxial pattern EP1 of the second source/drain pattern SD2 may be formed by performing the SEG process using the inner wall of the second epitaxial pattern EP2 as a seed layer.

In an embodiment, the second source/drain pattern SD2 may include a semiconductor element (e.g., SiGe) having a lattice constant greater than a lattice constant of the semiconductor element of the substrate 100. While the second source/drain pattern SD2 is formed, impurities (e.g., boron, gallium, and/or indium) that cause the second source/drain pattern SD2 to be p-type may be in-situ injected. As another example, after the second source/drain pattern SD2 is formed, impurities may be injected into the second source/drain pattern SD2.

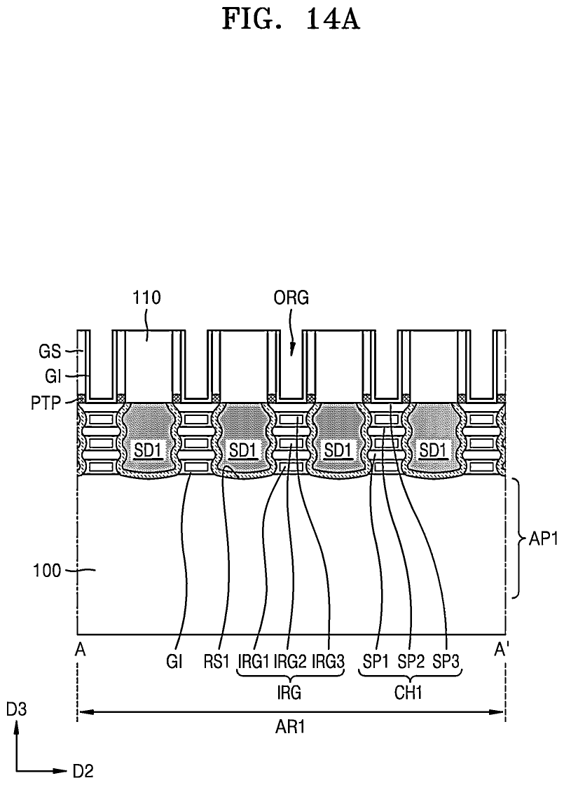

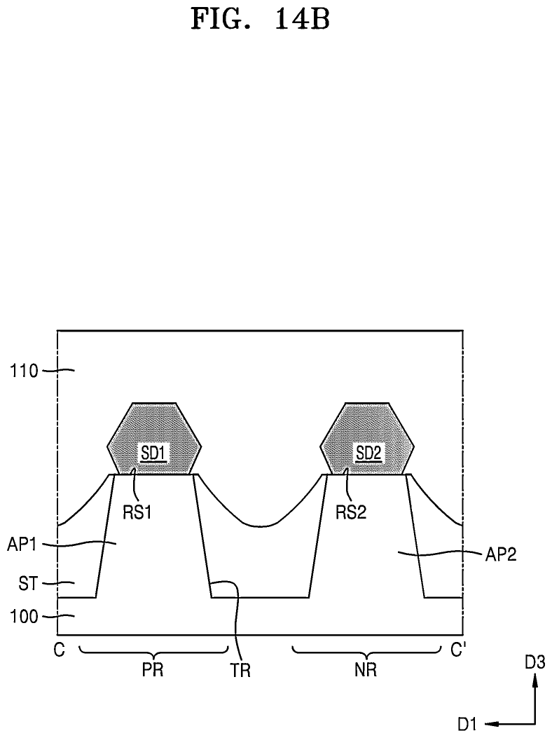

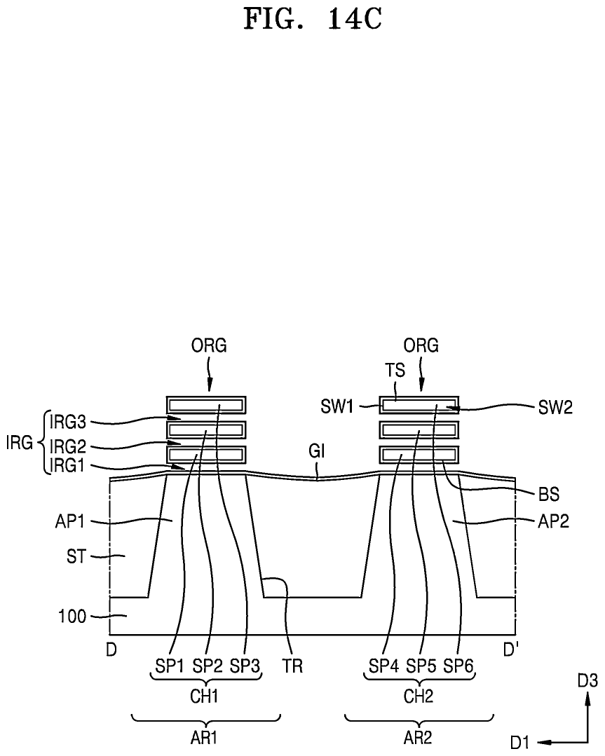

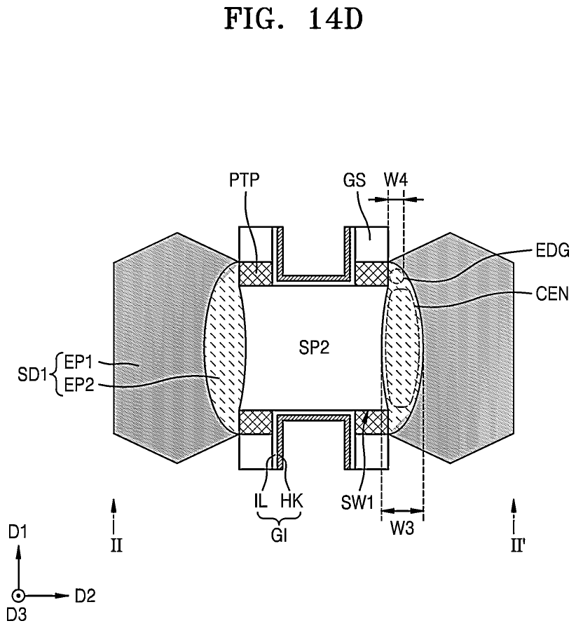

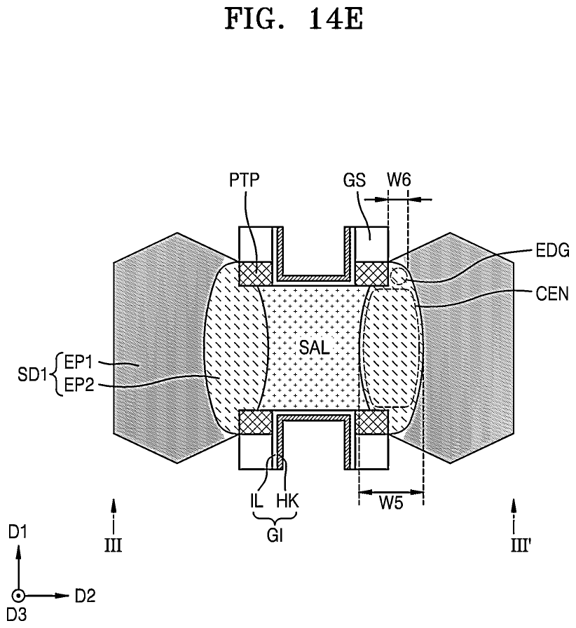

Referring to FIGS. 13C and 14A to 14E, the first interlayer insulating layer 110 disposed on (e.g., covering or overlapping) the first and second source/drain patterns SD1 and SD2, the hard mask patterns MP, and the gate spacers GS may be formed. As an example, the first interlayer insulating layer 110 may include a silicon oxide layer.

The first interlayer insulating layer 110 may be planarized until upper (e.g., uppermost) surfaces of the sacrificial patterns PP are exposed. Planarization of the first interlayer insulating layer 110 may be performed by using an etch back or chemical mechanical polishing (CMP) process. During a planarization process, the hard mask patterns MP may be completely removed. As a result, an upper (e.g., the uppermost) surface of the first interlayer insulating layer 110 may be coplanar with the upper (e.g., the uppermost) surfaces of the sacrificial patterns PP and the gate spacers GS.

The exposed sacrificial patterns PP may be selectively removed. An outer region ORG exposing the first and second channel patterns CHI and CH2 may be formed by removing the sacrificial patterns PP. Removing the sacrificial patterns PP may include, for example, wet etching using an etchant that selectively etches polysilicon.

A part of the protection pattern layer PTPA exposed through the outer region ORG may be removed. A part of the protection pattern layer PTPA may vertically overlap the sacrificial pattern PP. The part of the protection pattern layer PTPA that vertically overlaps the sacrificial pattern PP may be removed. As the part of the protection pattern layer PTPA is removed, the protection pattern PTP may be formed from the protection pattern layer PTPA. The protection pattern PTP may vertically overlap the gate spacer GS. The protection pattern layer PTPA (and the protection pattern PTP) may contact the second epitaxial pattern EP2 and the first, second, and third semiconductor patterns SP1, SP2, and SP3.

The sacrificial layers SAL exposed through the outer region ORG may be selectively removed to form inner regions IRG. Specifically, only the sacrificial layers SAL may be removed while remaining the first, second, and third semiconductor patterns SP1, SP2, and SP3 by performing an etching process of selectively etching the sacrificial layers SAL. The etching process may have a high etch rate with respect to silicon-germanium having a relatively high concentration of germanium. For example, the etching process may have a high etch rate with respect to silicon-germanium having a concentration of germanium greater than 10 at %.

During the etching process, the sacrificial layers SAL on the first and second active regions AR1 and AR2 may be removed. The etching process may be wet etching. An etching material used in the etching process may quickly remove the sacrificial layer SAL having a relatively high concentration of germanium.

The protection pattern PTP may not be removed during the etching process. This may be due to the fact that the protection pattern PTP includes a material having etch selectivity with the sacrificial layer SAL.

When the protection pattern PTP does not exist, a part of the first epitaxial pattern EP1 may be removed while the sacrificial layer SAL is removed through the etching process. This may be due to the fact that the width of the source/drain edge portion EDG of the second epitaxial pattern EP2 in the second direction D2 is less than the width of the source/drain center portion CEN in the second direction D2. As the source/drain edge portion EDG having a thin thickness is damaged through the etching process, the etching material may penetrate into the first epitaxial pattern EP1 and a part of the first epitaxial pattern EP1 may be removed. This may cause a defect in which the gate electrode GE and the first epitaxial pattern EP1 are short when forming the gate electrode GE. For the above reasons, the electrical characteristics and reliability of semiconductor devices may deteriorate.

According to the concept of the disclosure, the protection pattern PTP may be disposed between the semiconductor pattern SP1, SP2, or SP and the gate spacer GS. The protection pattern PTP may contact the semiconductor pattern SP1, SP2, or SP3 and the source/drain edge portion EDG of the second epitaxial pattern EP2. In addition, the protection pattern PTP may include a material having etch selectivity with the sacrificial layer SAL. For this reason, when performing an etching process on the sacrificial layer SAL, the source/drain edge portion EDG having a relatively thin thickness in the second direction D2 may not be damaged. This may prevent a defect in which the gate electrode GE and the first epitaxial pattern EP1 are short when forming the gate electrode GE. For the above reasons, the electrical characteristics and reliability of semiconductor devices may be improved.

By selectively removing the sacrificial layers SAL, only the first, second, and third semiconductor patterns SP1, SP2, and SP3 stacked on each of the first and second active patterns AP1 and AP2 may remain. First, second, and third inner regions IRG1, IRG2, and IRG3 may be formed through regions from which the sacrificial layers SAL have been removed.

Specifically, the first inner region IRG1 may be formed between the active pattern AP1 or AP2 and the first semiconductor pattern SP1, the second inner region IRG2 may be formed between the first semiconductor pattern SP1 and the second semiconductor pattern SP2, and the third inner region IRG3 may be formed between the second semiconductor pattern SP2 and the third semiconductor pattern SP3.

The gate insulating layer GI may be formed on the exposed first, second, and third semiconductor patterns SP1, SP2, and SP3. The gate insulating layer GI may be formed to extend around (e.g., at least partially surround) each of the first, second, and third semiconductor patterns SP1, SP2, and SP3. In some embodiments, the gate insulating layer GI may not be disposed between the semiconductor pattern SP1, SP2, or SP3 and the gate spacer GS (in the third direction D3).

Referring to FIGS. 7B, 7C, 14B, 15A, and 15B, the gate electrode GE may be formed on the gate insulating layer GI. The gate electrode GE may include first, second, and third portions PO1, PO2, and PO3 respectively formed in the first, second, and third inner regions IRG1, IRG2, and IRG3 and a fourth portion PO4 formed in the outer region ORG. The gate electrode GE may be recessed so that a height of the gate electrode GE is adjusted. The gate capping pattern GP may be formed on the recessed gate electrode GE.

Referring again to FIGS. 4 and 5A to 7C, the second interlayer insulating layer 120 may be formed on the first interlayer insulating layer 110. The second interlayer insulating layer 120 may include, for example, a silicon oxide layer. The active contacts AC extending in (e.g., penetrating) the second interlayer insulating layer 120 and the first interlayer insulating layer 110 and electrically connected to the first and second source/drain patterns SD1 and SD2, respectively, may be formed. The gate contacts GC extending in (e.g., penetrating) the second interlayer insulating layer 120 and the gate capping pattern GP and electrically connected to the gate electrodes GE, respectively, may be formed.

Forming each of the active contacts AC and the gate contacts GC may include forming a barrier pattern BM and forming a conductive pattern FM on the barrier pattern BM. The barrier pattern BM may be formed conformally and may include, for example, a metal layer/metal nitride layer. The conductive pattern FM may include, for example, a low resistance metal.

Before each of the active contacts AC and the gate contacts GC are formed, a metal-semiconductor compound layer SIC may be formed on the first source/drain pattern SD1 and the second source/drain pattern SD2. The metal-semiconductor compound layer SIC may be formed between the first source/drain pattern SD1 and the active contact AC and between the second source/drain pattern SD2 and the active contact AC.

The separation structures DB may be formed at a first boundary BD1 and a second boundary BD2 of the single height cell SHC, respectively. The separation structure DB may extend in (e.g., penetrate) the gate electrode GE from the second interlayer insulating layer 120 and (at least partially) extend into the active pattern AP1 or AP2. The separation structure DB may include an insulating material such as a silicon oxide layer and/or a silicon nitride layer.

The third interlayer insulating layer 130 may be formed on the active contacts AC and the gate contacts GC. The first metal layer M1 may be formed in the third interlayer insulating layer 130. The fourth interlayer insulating layer 140 may be formed on the third interlayer insulating layer 130. The second metal layer M2 may be formed in the fourth interlayer insulating layer 140.

While the inventive concept of the present application has been particularly shown and described with reference to embodiments thereof, it will be understood that various changes in form and details may be made therein without departing from the scope of the following claims.

What is claimed is:

1. A semiconductor device comprising:
a substrate that includes an active pattern;
a channel pattern on the active pattern, wherein the channel pattern includes a plurality of semiconductor patterns that are stacked and spaced apart from each other in a first direction;
a gate electrode on the plurality of semiconductor patterns, wherein the gate electrode extends in a second direction;
a gate spacer on a sidewall of the gate electrode in a third direction;
a source/drain pattern that is electrically connected to the plurality of semiconductor patterns, wherein the source/drain pattern includes a first epitaxial pattern and a second epitaxial pattern that is on a side surface of the first epitaxial pattern in the third direction; and
a protection pattern between at least one of the plurality of semiconductor patterns and the gate spacer,
wherein the protection pattern includes a material that has an etch selectivity with the first epitaxial pattern,
wherein the first direction is perpendicular to an upper surface of the substrate,
wherein the second direction is parallel with the upper surface of the substrate, and
wherein the third direction is parallel with the upper surface of the substrate and intersects the second direction.

2. The semiconductor device of claim 1, wherein the protection pattern is in contact with the second epitaxial pattern.

3. The semiconductor device of claim 1, wherein the protection pattern is in contact with the at least one of the plurality of semiconductor patterns.

4. The semiconductor device of claim 1, wherein the protection pattern includes silicon or silicon-germanium.

5. The semiconductor device of claim 4, wherein the protection pattern includes silicon-germanium, and
a concentration of germanium in the silicon-germanium of the protection pattern is greater than 0 at % and about 10 at % or less.

6. The semiconductor device of claim 4, wherein the protection pattern further includes phosphorus (P), boron (B), carbon (C), arsenic (As), indium (In), and/or gallium (Ga).

7. The semiconductor device of claim 1, wherein a width of the second epitaxial pattern in the second direction is greater than a width of the at least one of the plurality of semiconductor patterns in the second direction.

8. The semiconductor device of claim 1, wherein the at least one of the plurality of semiconductor patterns and the protection pattern have a unitary structure.

9. The semiconductor device of claim 8, wherein a width of the at least one of the plurality of semiconductor patterns in the second direction is equal to a width of the second epitaxial pattern in the second direction.

10. The semiconductor device of claim 1, wherein the second epitaxial pattern and the protection pattern have a unitary structure.

11. The semiconductor device of claim 10, wherein the second epitaxial pattern includes a center portion and an edge portion protruding from the center portion in the second direction,
wherein the protection pattern protrudes from the edge portion in the third direction, and
wherein a side surface of the protection pattern is closer to the gate electrode than a side surface of the center portion in the third direction.

12. A semiconductor device comprising:
a substrate that includes an active pattern;
a channel pattern on the active pattern, wherein the channel pattern includes a plurality of semiconductor patterns that are stacked and spaced apart from each other in a first direction;
a gate electrode on the plurality of semiconductor patterns, wherein the gate electrode extends in a second direction;
a gate spacer on a sidewall of the gate electrode in a third direction;
a source/drain pattern that is electrically connected to the plurality of semiconductor patterns, wherein the source/drain pattern includes a first epitaxial pattern and a second epitaxial pattern that is on a side surface of the first epitaxial pattern in the third direction; and
a protection pattern between at least one of the plurality of semiconductor patterns and the gate spacer,
wherein the protection pattern includes a material that has an etch selectivity with the first epitaxial pattern,
wherein the protection pattern is on an upper surface of an uppermost semiconductor pattern among the plurality of semiconductor patterns,
wherein the first direction is perpendicular to an upper surface of the substrate,
wherein the second direction is parallel with the upper surface of the substrate, and
wherein the third direction is parallel with the upper surface of the substrate and intersects the second direction.

13. The semiconductor device of claim 12, wherein the protection pattern overlap at least a part of a sidewall of each of the plurality of semiconductor patterns in the second direction.

14. The semiconductor device of claim 12, wherein the gate spacer is on the protection pattern.

15. The semiconductor device of claim 12, wherein the protection pattern is spaced apart from the first epitaxial pattern with the second epitaxial pattern therebetween.

16. The semiconductor device of claim 12, further comprising:
a device isolation layer that is adjacent the active pattern,
wherein the protection pattern is on an upper surface of the device isolation layer.

17. The semiconductor device of claim 12, further comprising:
a gate insulating layer between the gate electrode and the channel pattern,
wherein the protection pattern is spaced apart from the gate electrode with the gate insulating layer therebetween.

18. A semiconductor device comprising:
a substrate that includes an active region;
an active pattern in the active region;
a device isolation layer that is adjacent the active pattern;
a channel pattern on the active pattern, wherein the channel pattern includes a plurality of semiconductor patterns that are stacked and spaced apart from each other in a first direction;
a gate electrode on the channel pattern, wherein the gate electrode extends in a second direction;
a gate insulating layer between the gate electrode and the channel pattern;
a gate spacer on a sidewall of the gate electrode in a third direction;
a source/drain pattern that is electrically connected to the plurality of semiconductor patterns, wherein the source/drain pattern includes a first epitaxial pattern and a second epitaxial pattern that is on a side surface of the first epitaxial pattern in the third direction;
a protection pattern between at least one of the plurality of semiconductor patterns and the gate spacer, wherein the protection pattern includes a material that has an etch selectivity with the first epitaxial pattern;
a gate capping pattern on an upper surface of the gate electrode;
an interlayer insulating layer on the gate capping pattern;
an active contact that extends in the interlayer insulating layer and is electrically connected to the source/drain pattern;
a gate contact that extends in the interlayer insulating layer and the gate capping pattern and is electrically connected to the gate electrode; and
a first metal layer in the interlayer insulating layer,
wherein the first metal layer includes a power wiring, and first wirings that are electrically connected to the active contact and the gate contact, respectively,
wherein the first direction is perpendicular to an upper surface of the substrate,
wherein the second direction is parallel with the upper surface of the substrate, and
wherein the third direction is parallel with the upper surface of the substrate and intersects the second direction.

19. The semiconductor device of claim 18, wherein the protection pattern contacts the second epitaxial pattern.

20. The semiconductor device of claim 18, wherein the protection pattern contacts the at least one of the plurality of semiconductor patterns.
